(19) United States
(12) Patent Application Publication
(10) Pub. No.: US 2011/0023955 A1
(43) Pub. Date: Feb. 3, 2011

(54) LATERAL COLLECTION PHOTOVOLTAICS

(76) Inventors: Stephen J. Fonash, State College, PA (US); Wook Jun Nam, State College, PA (US)

Correspondence Address: MCNEES WALLACE & NURICK LLC, 100 PINE STREET, P.O. BOX 1166, HARRISBURG, PA, 17108-1166, US

(21) Appl. No.: 12/666,768

(22) PCT Filed: Jun. 26, 2008
(86) PCT No.: PCT/US08/68446

§ 371 Date: Oct. 25, 2010

Related U.S. Application Data
(60) Provisional application No. 60/946,250, filed on Jun. 26, 2007.

(30) Foreign Application Priority Data
Jan. 10, 2008 (US) 11/972491
Jan. 10, 2008 (US) PCT/US2008/050780

(51) Int. Cl. H01L 31/0224

(52) U.S. Cl. 136/256

(57) ABSTRACT

Lateral collection photovoltaic (LCP) structures based on micro- and nano-collecting elements are used to collect photogenerated carriers. In one set of embodiments, the collecting elements are arrayed on a conducting substrate. In certain versions, the collecting elements are substantially perpendicular to the conductor. In another set of embodiments, the micro- or nano-scale collecting elements do not have direct physical and electrical contact to any conducting substrate. In one version, both anode and cathode electrodes are laterally arrayed. In another version, the collecting elements of one electrode are a composite wherein a conductor is separated by an insulator, which is part of each collector element, from the opposing electrode residing on the substrate. In still another version, the collection of one electrode structure is a composite containing both the anode and the cathode collecting elements for collection. An active material is positioned among the collector elements.

### BACKGROUND

The present application relates generally to electronic and opto-electronic devices and a production method for the production of electronic and opto-electronic devices from an interpenetrating network configuration of nano structured high surface to volume ratio porous thin films with organic/inorganic metal, semiconductor or insulator material positioned within the interconnected void volume of the nano structure. The present application relates more specifically to lateral collection photovoltaic (LCP) structures.

Today, nanoparticles are proposed for, and used for, providing a high surface area to volume ratio material. Besides the large surface area they provide, nanoparticles can be embedded in organic/inorganic semiconductor/insulator materials (nano composite systems) to obtain a high interface area that can be exploited in, for example, the following optoelectronic and electronic applications: (a) charge separation functions for such applications as photovoltaics and detectors; (b) charge injection functions for such applications as light emitting devices; (c) charge storage functions for capacitors; and (d) ohmic contact-like functions for such applications as contacting molecular electronic structures.

There are difficulties with nanoparticles, however. These include their handling and, for electronic and opto-electronic uses, they also include the question of how to achieve electrical contact. In one approach for making optoelectronic devices from nanoparticle composite systems, isolated nanoparticles are diffused into a matrix of organic material. Each nanoparticle or nanoparticle surface must be electrically connected to the outside (by a set of electrodes) for electrical and opto-electronic function. This is achieved when the nanoparticles are arranged so that they are interconnected to the electrodes providing continuous electrical pathways to these particles. However, with the use of isolated nanoparticles, these particles will often fail to make good electrical contacts even if the volume fraction of nanoparticles is made close to unity.

Conventional photovoltaic operation uses some version of the basic horizontal structure seen in FIG. 1. Here light impinges on the horizontal layers and the resulting photogenerated electrons and holes, electrons and holes resulting from photogenerated excitons, or both are charge-separated with positive charge collected at the +charge-collecting electrode (anode) and negative charge collected at the −charge-collecting electrode (cathode), respectively. In the structure shown in FIG. 1, the device is composed of a p-type and an n-type solid semiconductor material, which semiconductor materials are functioning as the light absorbers, and as junction-formers creating the so-called built-in electric field providing the driving mechanism for charge separation. Other horizontal structures may use electron and hole affinity differences (band steps or band off-sets), with or without the built-in electric field mechanism, to drive charge separation. For photovoltaic action in FIG. 1, charge separation must result in electrons being collected at one electrode, the cathode, (bottom in FIG. 1) and holes being collected at the other electrode, the anode, (top in FIG. 1) giving rise to a current which can do external work (e.g., lighting a light bulb in FIG. 1).

Horizontal photovoltaic structures may be described in terms of two lengths: the absorption length, which is the distance light penetrates into the active (absorber) layer(s), e.g., the p-type and n-type layers shown in FIG. 1, before being effectively absorbed, and the collection length, which describes the distance in the active layer(s) over which photogenerated charge carriers can be separated and collected to the electrodes for use externally. In the case of photogeneration of excitons the collection length to be considered is usually the exciton diffusion length. The exciton diffusion length describes how far the excitons move by diffusion. The collection and the absorption lengths in horizontal structures such as the one shown in FIG. 1 are essentially parallel to one another. In these horizontal structures, the electrodes are usually solids although one or both can be electrolytes or some combination of electrolytes and solids. The electrodes can also be a porous solid structure or some combination of non-porous and porous materials.

The fact that the absorption and the collection lengths in the horizontal structure of FIG. 1 are essentially parallel means they are not independent. In horizontal structures such as that of FIG. 1, for effective photovoltaic operation, the appropriate collection length or lengths of the top active layer must be at least long enough to allow carriers generated by absorption in the top active layer to be collected and the appropriate collection length or lengths of the bottom active layer should be at least long enough to allow carriers generated by absorption in the bottom active layer to be collected and should be at least as long as the absorption length in that material for effective operation.

One alternative to the horizontal structure of FIG. 1 is a lateral collection approach that uses single crystal silicon structures using silicon (Si) wafer material. The Sliver® solar cell has been developed based on this concept. However, this lateral collection approach makes use of single crystal wafer silicon. The goal of the Sliver® approach is to use conventional silicon wafer-type material but, through the use of lateral collection, to reduce the amount of this expensive form of Si needed for the solar cell. In this process, single-crystal silicon is, for example, cut in 50 μm thick, 100 mm long, and 1 mm deep strips. The surrounding silicon holds these strips together. The Sliver® solar cell uses conventional silicon technology, but in a “slivered” configuration.

Intended advantages of the disclosed systems and/or methods presented herein teach configurations for the improvement of photovoltaic structures preferably fabricated from relatively low cost materials. Other features and advantages will be made apparent from the present specification. The teachings disclosed extend to those embodiments that fall within the scope of the claims, regardless of whether they accomplish one or more of the aforementioned needs.

### SUMMARY

The present application addresses some of the problems in the field by using disposed high surface to volume ratio materials, as opposed to other techniques such as the “slivering” approach. The disposed high surface to volume ratio materials permit a manageable high interface area which is easily contacted electrically.

The present application involves positioning a nanostructured or microstructured high surface area to volume ratio material on a conductor or conductive substrate or a patterned set of electrodes on a substrate. The basic elements (building blocks) of this nanostructure (or microstructure) are embedded in a void matrix with the attributes of high surface to volume ratio but with electrical connectivity to the conductor. Once the void network of the film material is filled with an active material, a composite is formed with high interface area. Furthermore, each component of the composite structure is conformally connected. Hence, any region of the composite system including the interface has continuous electrical connection to the outside.

One embodiment of the present application is directed to a method of fabricating an electronic/optoelectronic device from an interpenetrating network of a nanostructured (or microstructured) high surface area to volume ratio material and an organic/inorganic matrix material having the steps of: a) obtaining a high surface area to volume ratio film material onto an electrode substrate (or a patterned electrode substrate), such that any region of this film material is in electrical connectivity with the electrode substrate by virtue of the morphology. For example, the film material may comprise an array of nano and/or micro-protrusions electrically connected to the electrode substrate and separated by a void matrix; b) filling the void matrix of the high surface to volume film with an organic/inorganic solid or liquid material; and c) defining an electrode or set of electrodes onto the organic or inorganic intra-void material embedded in the void matrix.

Another embodiment of the application uses an array of nano and/or microprotrusion collecting elements and spacing for lateral collection photovoltaic (LCP) structures. The collecting elements may be metals, semiconductors or both and, in some embodiments, involve insulators. In one set of embodiments, the collecting elements (constituting the anode or cathode) are arrayed on a conducting layer or substrate, in which case they are electrically and physically in contact with the conductor. In such a configuration, the array of elements and the conductor constitute the electrode. The collecting elements may themselves also serve as the conductor and therefore may be the complete electrode in another embodiment. These collecting elements are substantially perpendicular to the conductor. In all the described embodiments, an absorber, or more generally an active material, is disposed among the collector elements. As used herein, active material may include a material with one or more absorber materials combined with none, one or more collector (separator) materials or materials that improve the interface contact between the active materials and the electrodes or conductors. All collector elements and absorber or active materials are disposed in some manner including, etching, physical deposition, chemical deposition, in situ growth, stamping, or imprinting. The collector element material can be a conductor or semiconductor, which may also function as an absorber. This application also includes several different shapes for the collector structure and its elements. The inter-collector element positioned absorber or active material may be organic or inorganic and crystalline (single or poly-crystalline) or amorphous. The absorber or active material may be solid or liquid, or some combination thereof. In a further embodiment, the collecting elements are nano-elements grown from nanoparticle catalysts or discontinuous catalyst film. The collecting elements may not necessarily be arrayed perpendicular to the conductor in these embodiments.

In another set of embodiments for the lateral collection concept, the substrate is not conducting and anode and cathode elements are laterally arrayed side by side. In a further set of embodiments for the lateral collection concept, at least the anode or the cathode, which is composed of an array of nano and/or micro-scale collecting elements, does not have direct physical and electrical contact to any conducting substrate. In one embodiment, one electrode is a composite wherein a conductor is separated by an insulator, which is part of each collector element, from the opposing electrode and this opposing electrode is a conductor covering a surface. In still another embodiment, the collection structure is a composite containing both the anode and cathode collecting elements for lateral collection. The opposing electrode may or may not be in contact with a conductor covering a surface.

A further embodiment is directed to a photovoltaic device having a first conductive layer, a collection structure in physical and electrical contact with the first conductive layer, an active layer disposed adjacent to the first conductive layer and in contact with all surfaces of the collection structure, and a second conductive layer disposed opposite the first conductive layer and in contact with the active layer. The active layer has an absorption length and a collection length. The collection structure includes a plurality of collector elements positioned substantially perpendicular to the conductive layer. The plurality of collector elements extending from the first conductive layer by a distance corresponding to the absorption length of the active layer and the plurality of collector elements being spaced apart by a distance corresponding to two times the collection length of the active layer.

Certain advantages of the embodiments described herein lie in applications in power generation, such as photovoltaic cell use. The disclosed embodiments may also be applicable to photodetectors, chemical sensors, electroluminescent devices and light emitting diode structures. In the case of the electroluminescent devices and light emitting diode structures, carrier flow direction is reversed from photovoltaic devices and carriers are injected instead of collected. The disclosed embodiments, with their large electrode areas and various electrode configurations, have application to chemical batteries, fuel cells, and capacitors.

Alternative exemplary embodiments relate to other features and combinations of features as may be generally recited in the claims.

### BRIEF DESCRIPTION OF THE FIGURES

FIG. 1 illustrates a prior art device incorporating conventional photovoltaics.

FIG. 2 illustrates a lateral collection photovoltaic structure.

FIG. 3 illustrates a collecting structure with column-like elements.

FIG. 4 illustrates a collecting structure with honeycomb-like elements.

FIG. 5 illustrates a collecting structure with fin-like elements.

FIG. 6 illustrates an embodiment using amorphous-Si.

FIG. 7 illustrates growth of the absorbing active layer using a catalyst layer positioned among the collector elements.

FIG. 8 illustrates a patterned catalyst on the substrate.

FIG. 9 illustrates columns/rods grown by the VLS approach.

FIG. 10 illustrates nano-elements grown from catalytic nano-particles, embedded in the active layer of a photovoltaic structure.

FIG. 11 illustrates nano-elements grown from a discontinuous catalyst film embedded in the active layer of a photovoltaic structure.

FIG. 12 illustrates an electrode structure of a lateral collection photovoltaic device.

FIG. 13 illustrates a cross-section of the lateral collection photovoltaic device of FIG. 12.

FIG. 14 illustrates a composite electrode structure with one electrode positioned on a second electrode which is on the substrate.

FIG. 15 illustrates a cross-section of a photovoltaic device with the composite electrode structure of FIG. 14.

FIG. 16 illustrates a composite electrode structure with each component including both electrodes.

FIG. 17 illustrates a cross-section of a photovoltaic device with the composite electrode structure of FIG. 16.

FIG. 18 illustrates a cross-section of a photovoltaic device with an insulator separating the electrodes.

FIGS. 19A-19H illustrate an exemplary lateral collection structure fabricated using metal induced solid phase crystallization in which one set of electrode elements serves as the SPC catalyst and electrode while another set functions as the counter-electrode. In this example, Ni is employed for one set of electrode elements to induce solid phase crystallization of a-Si. In this embodiment processing to create the structure begins with a sacrificial material which is later replaced with the material to undergo SPC.

FIG. 20 illustrates an array of alternating anode and cathode lateral collection elements.

FIG. 21 illustrates an exemplary lateral collection structure fabricated using metal induced solid phase crystallization in which one set of electrode elements serves as the SPC catalyst and electrode while another set functions as the counter-electrode. In this embodiment, processing to create the structure begins with the material to undergo SPC being present.

FIG. 22 illustrates an exemplary lateral collection structure fabricated using solid phase crystallization in which one set of electrode elements serves as the metal catalyst inducing SPC and as one electrode while another set functions as the counter-electrode. In this structure a seed layer for electro-deposition of the first set of electrode elements is disposed across the substrate and the trenches of two depths are imprinted into a resist to begin pattern transfer.

FIGS. 23A-23H illustrate an exemplary lateral collection structure fabricated using silicon induced solid phase crystallization in which one set of electrode elements serves as the SISPC catalyst and as one electrode while another set functions as the counter-electrode. In this embodiment, a VLS catalyst layer for growing low temperature Si for the first set of electrode elements and for serving as the SISPC catalyst is disposed at the bottom of a first set of trenches.

FIGS. 24A-24H illustrate an exemplary lateral collection structure and its required processing are similar to that of FIGS. 23A-23H except processing begins with a sacrificial material present. This then allows VLS catalyst material to be etched away before the material to be crystallized by SISPC is disposed.

FIG. 25 illustrates an exemplary lateral collection structure fabricated using silicon induced solid phase crystallization in which one set of electrode elements serves as the SISPC catalyst and as one electrode while another set functions as the counter-electrode. In this embodiment, a VLS catalyst layer for growing low temperature Si for the first set of electrode elements and for serving as the SISPC catalyst is disposed across the whole substrate.

FIG. 26 illustrates an exemplary lateral collection structure fabricated using silicon induced solid phase crystallization in which one set of electrode elements serves as the SISPC catalyst and as one electrode while another set functions as the counter-electrode. In this embodiment, the catalyst for VLS growth of the Si of the first set of electrode elements is disposed across the substrate and the trenches of two depths are imprinted into a resist to begin pattern transfer.

FIGS. 27A-27H illustrate an exemplary lateral collection structure fabricated using metal seed, VLS catalyst, or both layers is disposed across the whole substrate. Two trench depths are imprinted into the resist. The first set of electrode elements is attained by etching the deeper trench set in the resist down to the lowest metal layer and growing the electrode elements by electro-deposition or VLS. The second set of electrode elements is attained by etching the shallower trench set in the resist down to the nearer metal layer and growing the electrode elements of the counter-electrode by electro-deposition or VLS

Wherever possible, the same reference numbers will be used throughout the figures to refer to the same or like parts.

### DETAILED DESCRIPTION OF THE EXEMPLARY EMBODIMENTS

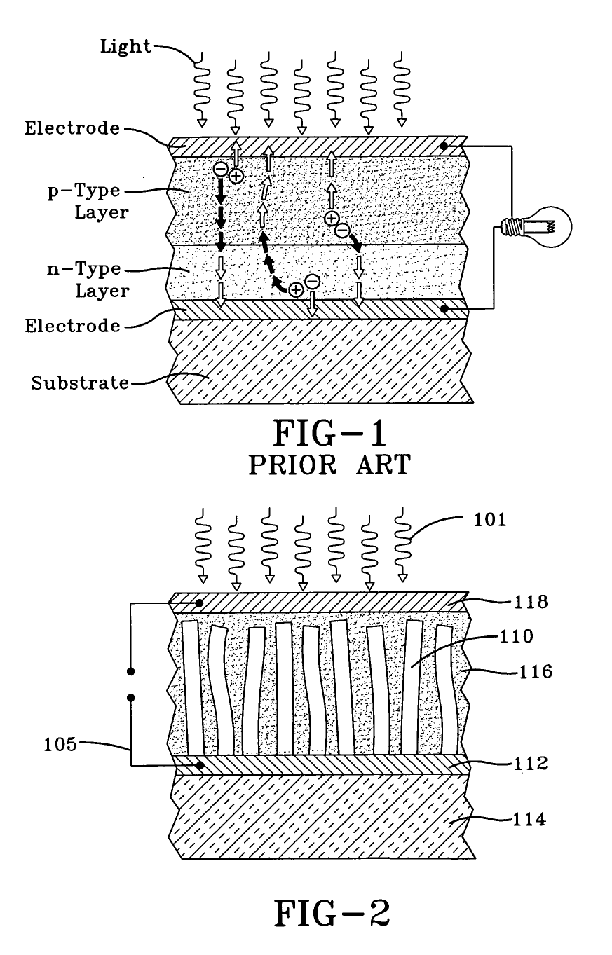

FIG. 2 shows a lateral collection photovoltaic structure. The lateral collection structure of FIG. 2 has many of the features of the horizontal configuration of FIG. 1, except that the collection lengths involved in the structure of FIG. 2 are essentially perpendicular to the absorption length. Thus, the collection and absorption lengths have become independent of one another. The lateral collection structure of FIG. 2 can have a collecting interface within a collection length of essentially all of the active material. The lateral collection structure of FIG. 2 is described in detail in U.S. Pat. No. 6,399,177, U.S. Pat. No. 6,919,119 and U.S. Patent Application Publication No. 2006/0057354, which patents and application publications are hereby incorporated by reference into the application in their entirety.

The lateral collection photovoltaic structure of FIG. 2 can be fabricated from an interpenetrating network of a film material and a metal, semiconductor, or insulator material forming a large interface area. The high surface area to volume film material can include collector structure 110, i.e., an array of one or more collector elements, e.g., an array of nano- and/or micro-protrusions, separated by voids or a void matrix, on a a conductive layer 112, which conductive layer 112 is on a non-conductive substrate 114. In another embodiment, the substrate can be a conductive material and can operate as the conductive layer. The combination of the collector structure 110 and the conductive layer 112 can operate as an electrode for the photovoltaic structure.

The nano- and/or micro-protrusions can have various other morphologies as long as the nano- and/or micro-scale basic elements each have continuous charge conduction paths to the conductive layer or conductor 112 or themselves play the role of conductor. As used herein, nano-scale refers to dimensions between about 1 nm and about 100 nm and micro-scale refers to dimensions between about 100 nm and less than a 1000 μm. The void volume can be filled with an appropriate active layer 116 such as an organic/inorganic semiconductor material. A second conductor (or set of nano- and/or microprotrusion elements in contact with a second set of conductors) 118 is positioned onto the active layer 116 forming the device counter electrode. Contacts 105 are in electrical connection with conductors 112 and 118 to provide a connection to the outside world.

In another embodiment, the basic elements of the high surface area to volume film material can include nano-structures, e.g., nanotubes, nanorods, nanowires, nanocolumns or aggregates thereof, oriented molecules, chains of atoms, chains of molecules, fullerenes, nanoparticles, aggregates of nanoparticles, and any combinations thereof or microstructures. The basic materials of the high surface area to volume film can comprise silicon, silicon dioxide, germanium, germanium oxide, indium, tin, gallium, cadmium, selenium, tellurium, and alloys and compounds thereof, carbon, hydrogen, oxygen, semiconductors, insulators, metals, ceramics, polymers, other inorganic material, organic material, or any combinations thereof. The electrode-elements structure high surface area to volume film can be deposited onto the conductive layer 112 or on a patterned substrate (if the substrate is conductive) by, for example, chemical vapor deposition, plasma-enhanced chemical vapor deposition, physical vapor deposition, or electrodeposition. The film may also be obtained by etching or electrochemical etching.

The active layer material may comprise organic and inorganic semiconductors, semiconductor particles, metal particles, an organometallic, a self assembling molecular layer, a conjugated polymer, and any combinations thereof. The active layer material or its precursors may be applied in liquid form, molten form, dissolved in a solvent, or by electrochemical means. Additionally, the active layer material may be embedded into the void matrix by exposing the thin film material to the vapor of the active layer material or its precursors, thus causing the vapor to condense inside the void matrix. Such vapor may be produced by chemical vapor deposition and physical vapor deposition techniques including nebulization.

As discussed above, light 101 impinges on the structure and the resulting photogenerated electrons and holes, electrons and holes resulting from photogenerated excitons, or both are charge-separated with positive charge collected at the +charge-collecting electrode (anode) and negative charge collected at the −charge-collecting electrode (cathode), respectively. For photovoltaic action, charge separation must result in electrons moving to one electrode, the cathode, and holes moving to the other electrode, the anode, giving rise to a current. As mentioned above, the collection structure 110 and the conductive layer 112 can operate as either the anode or the cathode.

If excitons are produced by photoexcitation (i.e., are photogenerated), the collector elements of the collection structure 110 should also be able to collect (by diffusion in the active layer 116) any excitons, which are not converted into electrons and holes in the active region 116, to collector element surfaces in order to enable exciton conversion, at these surfaces, into free electron and hole pairs. The collection of excitons establishes a lateral exciton collection length. If the active layer 116 is composed of multiple components, the lateral exciton collection length is an effective exciton collection length.

If electrons and holes are produced directly by photoexcitation (i.e., are photogenerated) or produced by photogenerated excitons breaking up in the active material, the collector elements of the collection structure 110 should be able to collect (by drift, band edge variations, diffusion, and any combination thereof in the active layer 116) to collector element surfaces either the free electrons or holes. The collection of electrons or holes establishes a lateral free carrier collection length. If the active layer 116 is composed of multiple components, the lateral free carrier collection length is the effective free carrier collection length. Generally, the selection of the free carrier (electrons or holes) determines the inter-element array spacing C for the collector structure 110, which is based on which free carrier has the poorer mobility, or equivalently, the poorer collection length. If excitons are to be broken up by the collection element surfaces, the collection structure 110 can be designed such that the exciton collection length is no less than about half the inter-element array spacing C of the collection structure 110. The other free carriers (electrons or holes) not taken up by the collection structure 110 should have a collection length, termed the vertical collection length, of substantially about the longest distance to the counter electrode.

If excitions are the principal entities collected at the collector element surfaces, the collection structure 110 can be designed with the excitons determining the lateral collection length and thereby determining the inter-element or collector structure array spacing C. If free carriers are the principal entities collected at the collector element surfaces, the collection structure 110 can be designed so that the carrier collected is the one with the lower mobility. In this case, the collection length of the free carrier is the lateral collection length and the lateral collection length determines the collector structure spacing C. Whether the collecting elements of the collection structure 110 are principally collecting excitons or free carriers, the collection structure 110 provides a collecting interface within the appropriate collection length of essentially all of the active material. The collection structure 110 may or may not itself be an absorber. This flexibility is possible since the collection structure 110 (and its corresponding collector elements), if chosen not to be an absorber, should present at least one dimension W to the incoming light 101 which is preferably in the nano-scale thereby creating a minimized dead (non-light-absorbing) volume. Depending on the material used for the collection structure 110, the collection structure 110 may, in addition to collecting photogenerated entities (excitions and/or free carriers), be (1) an absorber, (2) used for enhanced light reflection and trapping, (3) used to attach quantum dots, monolayers, or other materials to enhance performance, and (4) the source for plasmons for interaction with the absorption process. In addition, the active materials have all the possibilities discussed above, as do the conductor materials.

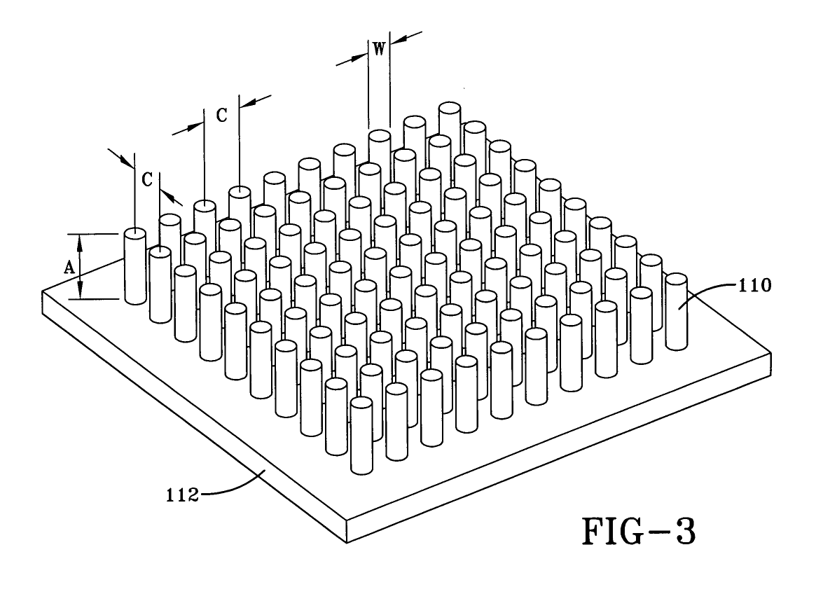

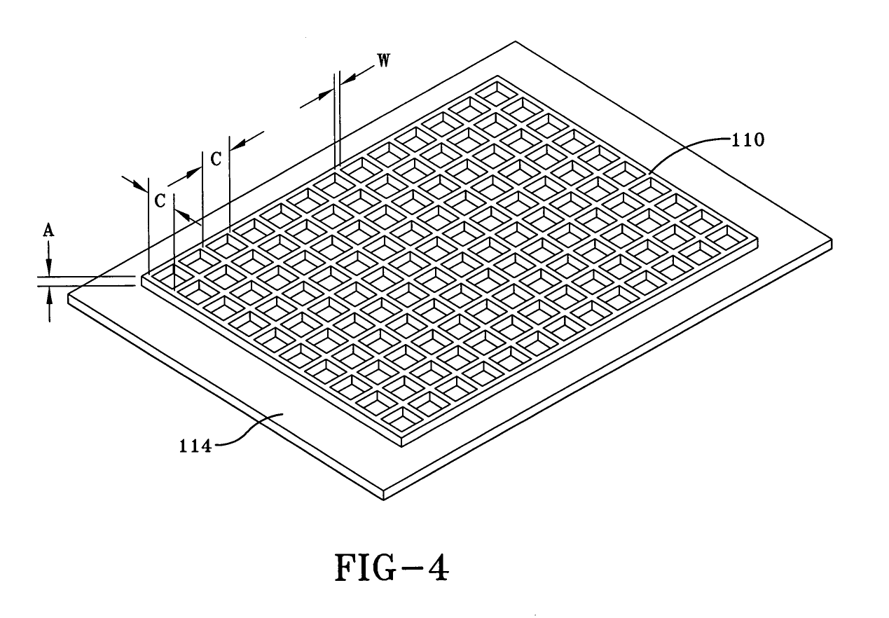

Various shapes may be used for the lateral collection structures of the application. FIGS. 3-5 show three embodiments of collection structures 110 (and corresponding collector elements). The collection structure embodiments of FIGS. 3-5 and combinations and variations thereof, may be disposed on a conductor 112. However, in the embodiments of FIGS. 4 and 5, the collection structure 110 may serve as the electrode without a conductor and be disposed directly on the substrate 114. FIG. 3 shows a collection structure composed of an array of column-like collector elements similar to FIG. 2. FIG. 4 is a collection structure composed of an array of “honeycomb-like” collector elements, whereas FIG. 5 is a collection structure composed of an array of “fin-like” collector elements. While FIGS. 3-5 illustrate several examples of collection structures 110, it is to be understood that any suitable lateral collection structure can be used.

When using collection structures 110 in a photovoltaic cell, the characteristic array spacing dimension C seen in FIGS. 3-5 can be chosen to be approximately twice the lateral collection length (exciton or free carrier, as appropriate) of the active material used to fill the voids or areas between the collector elements or the inter-collector element region. The active material disposed in the inter-collector element region in FIGS. 3-5 is such that it has an interface for collection with the collection or collector structure 110 of these embodiments. The dimension A in FIGS. 3-5 is based on the absorption length of the active (or absorber) material and the vertical collection length, when appropriate. As noted, active materials contain an absorber material or materials and may be combinations of organic or inorganic semiconductor materials, light absorbing molecules and may contain dyes, nanoparticles such as quantum dots, or plasmon-generating metal particles, or some combination thereof. Either or both of the conductors or elements of the electrodes in a photovoltaic structure based on the collection structures 110 of FIGS. 3-5 may be a transparent, conducting material including, for example, tin oxide, zinc oxide or indium tin oxide. Reflecting structures may be constructed behind or using one of the conductors of the electrodes. The collector structure 110 may also be the entire electrode (i.e., there is no conductive layer connected to the collector structure), reflector/light trapping structure or both.

In a photovoltaic structure based on the collection structure 110 of FIGS. 3-5, the active materials have at least one dimension C of the order of twice the lateral collection length and another dimension A of the order of the absorption length or, if appropriate, the vertical collection length. When the vertical collection length is involved, dimension A can be the lesser of the absorption length and the vertical collection length. In a photovoltaic structure based on the collection structure 110 of FIGS. 3-5, both the active (absorber) and collector materials can be produced using techniques such as etching and/or deposition, in situ growth, stamping, or imprinting. Deposition techniques that may be used include chemical vapor deposition, liquid deposition including electrochemical growth methods, and physical vapor deposition approaches.

The active material resides among the collecting elements of the collector structure 110. The active material may be formed using a number of approaches. A discussion of several, but not all, such approaches is provided below.

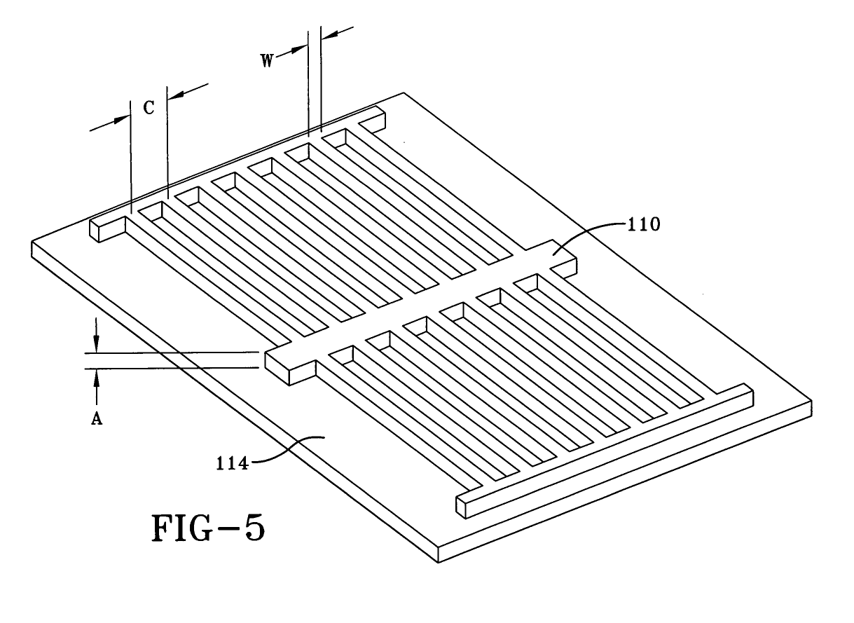

The active material may be a deposited thin film amorphous silicon (a-Si:H). Typical thin film a-Si:H can have a collection length of about 0.1 μm to about 1 μm and an absorption length of less than about 1 μm. FIG. 6 shows an embodiment of a photovoltaic device or cell incorporating the column, honeycomb, or fin collector elements of the collector structure 110 (shown in cross-section) of FIGS. 3-5. The array spacing between the collector elements of the collector structure is in the range of about 0.2 μm to about 2 μm, i.e., into or in the micro-scale, for the a-Si:H material. The thin film a-Si:H of the embodiment of FIG. 6 can be doped as needed and deposited using standard techniques such as plasma deposition or low pressure chemical vapor deposition (LPCVD). The former can involve temperatures as low as about 200° C. or lower. The latter usually involves temperatures of approximately 550° C. or lower. In the embodiment of FIG. 6, the collector structure 110 has been chosen to be a metal and the top conductor or electrode 118 is a transparent conducting oxide with a doped a-Si:H layer 120 under the top electrode 118 and a doped or undoped a-Si:H layer 122 under the doped a-Si:H layer 120. In another embodiment, the a-Si:H may be arranged such that the layer under the top electrode 118 is n- or p-type material and the collector structure 110 may be a semiconductor material. If collector structures 110 with collector elements such as the fin or honeycomb-like collectors are used, it is possible to omit the electrode under the collector structure 110, i.e., structures which provide a lateral electrical continuous path may function also as electrodes and be connected to electrical leads 105. Furthermore, the collector structures 110 may be used to adhere, using standard tethering and attachment methods, interface layers, particles such as quantum dots, or particles that give multiple electron/hole pair generation per absorbed photon. The collector structures 110 also may serve as reflecting/light trapping structures or parts thereof and as sources of plasmons for impacting absorption processes. As in all embodiments, the material composition of a collector structure 110 (and corresponding collector elements) is selected to address collector resistance, the requisite workfunction difference (with the counter electrode) to aid in setting up the built-in collecting electric field, or to have band steps (off-sets) to aid in collection, or some combination thereof

The collector structure 110 may be produced by various techniques including (1) etching, (2) deposition, (3) in situ growth, (4) stamping or by (5) imprinting, including, impressing in (inlaying) the actual collector structure 110. In the deposition technique, an exemplary approach to fabrication is to have the collector pattern transferred to a patterned block co-polymer or patterned resist obtained using lithography techniques, which may include beam, imprint, stamp or optical methods. For example, the collector material can be deposited into the resulting patterned block co-polymer or resist as a thin film and then patterned by lift-off, producing structures such as those seen in FIGS. 3-5. When a block-co-polymer material is used deposition can be carried out with the block-co-polymer in place but one phase removed. The regions where the removed phase had resided become the positions of the collector elements. The remaining polymer can then be removed using standard lift-off techniques.

In the in situ growth case, the elements of the collector structure 110 are grown in a shape such as those of FIGS. 3-5. The growth of the elements of the collector structure 110 may be accomplished, for example, using a vapor-liquid-solid (VLS) technique wherein a pattern catalyst is first positioned on a surface (if the collector structure 110 is to be the entire electrode) or on the bottom conductor 112 which is on a surface (if the collector structure 110 is to be residing on a conductor, which may be patterned). The catalyst may be disposed on a patterned conductor by techniques such as self-assembly (e.g., catalyst particles tethered onto patterned Au using thiol bonds) or it may be patterned using, for example, any of the etching or deposition techniques discussed above for patterning a deposited material as well as by other techniques such as ink jet printing or the dip pen approach. The collector elements themselves are then grown from a precursor at the catalyst positions at the required temperature. For example, if the collector structure 110 is to be silicon, then the precursor is a silicon bearing compound such as silane and the temperature, using gold (Au) as the catalyst, can be around 550° C. or less. Material bearing a dopant may also be used with the catalyst or with the precursor if the silicon (Si) is to be doped. Any residual catalyst present after growth may be removed from the collector elements using an etchant specific to the catalyst (e.g., a gold etchant for an Au catalyst for Si growth). Nanoparticle catalysts for collector growth can be employed to automatically attain advantageous aspect ratios (A/W) in FIGS. 3-5, i.e., greater than one, for collector structures 110 where W is a measure of the collector element characteristic width. For example, if a nanoparticle catalyst for carbon nanotubes or wires is stamped onto a surface in the collector pattern, nanotube or wire growth can be exploited to give essentially perpendicular collector elements with advantageous aspect ratios. These stuctures can be used, as manufactured, as the collector elements, or coated (e.g., by electro-chemical means).

In the imprinting case, the collector structure 110, which may be on a substrate including glass, metal foil, or plastic, is positioned by being pressed (in layered) into an already present active (absorber) material thereby also resulting in the structure of FIG. 6. Collector structures 110 for this in lay approach are produced in the same way collector structures 110 are produced in the discussion above, e.g., they may be produced by etching or deposition and techniques used may employ block-co-polymers, printing or stamping techniques, optical or e-beam lithography, and deposition/lift off or other approaches such as electrochemical deposition. In this embodiment, the collector elements may be on a conducting surface or be the entire electrode themselves.

Catalyst positioning and techniques such as deposition by nebulization or by vapor-liquid-solid (VLS) deposition may also be used to form the active material of the inter-collector-element region or the absorber or collector structure 110. The collector structure 110 may also be an absorber itself. In all these structures, light may impinge from the side (top or bottom) on which the collector structure 110 is placed or from the other side. Thus, in these types of structures, light can impinge the top side, the bottom side or both the top and bottom sides, except when a reflector is used in the structure. In the top/bottom electrode arrangements (e.g., FIGS. 2-6), the collector structures 110 may be positioned at the top or bottom or both the top and bottom, if so desired.

In another embodiment, the active material positioned between the collector elements is thin film crystalline Si produced by one of three techniques: (1) crystallization of a-Si, (2) deposition of polycrystalline Si, or (3) a catalytic process such as vapor-liquid-solid (VLS) deposition.

Amorphous Si (a:Si) can be converted into polycrystalline silicon (poly-Si) using solid phase crystallization (SPC) done by furnace annealing or rapid thermal annealing (RTA). Thin film amorphous silicon, deposited between the collector elements, can be converted by SPC into poly-Si absorber material after the entire cell is fabricated or after the a-Si materials are deposited. If RTA is used, an example temperature-time step is given by noting that 750° C. RTA exposure can produce the needed crystallization in less than one minute. Typical SPC poly-Si can have a collection length of ˜10 μm and an absorption length of ˜10 μm. The collection length and absorption length determine the dimensions C and A of the collector structure 110 whose elements can have nano-scale W values, e.g., column diameter, fin thickness, or honeycomb thickness, if a non-absorber. If the elements are an absorber material, these diameter/thickness W dimensions need not be in the nano-scale, but would be optimized for efficiency while maintaining the dimensions C and A.

Thin film polycrystalline silicon and/or germanium can be directly deposited as an absorber positioned between collector elements, e.g., by LPCVD at temperatures of approximately 580° C. or higher. Typical deposited poly-Si can have a collection length of about 5 μm and an absorption length of about 10 μm. The collection length and absorption length determine the dimensions C and A of the collector structure 110.

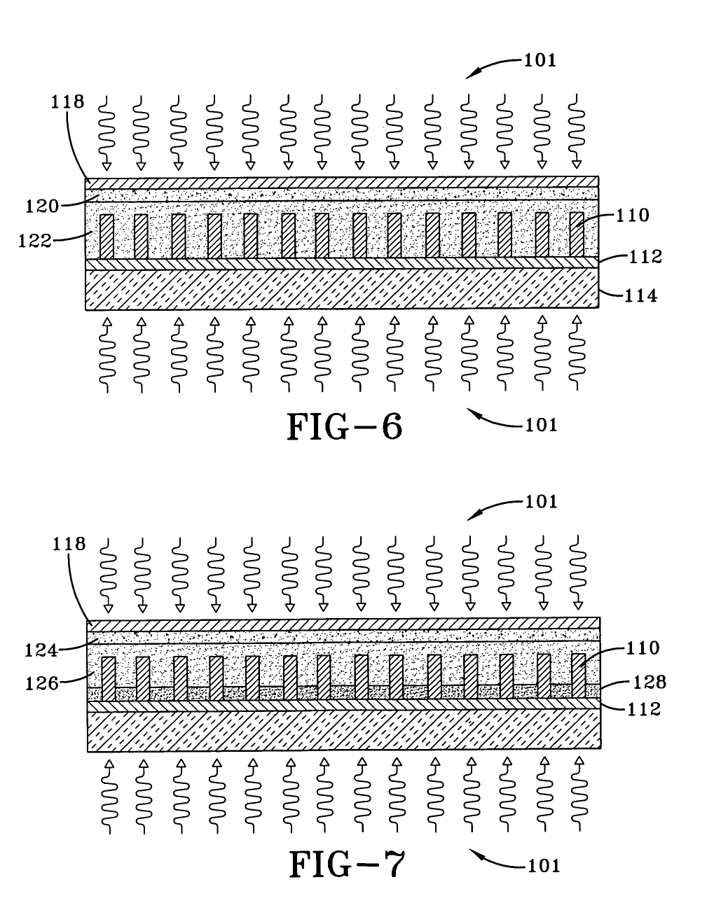

Thin film crystalline silicon and/or germanium and other absorber materials can be directly deposited by vapor-liquid-solid (VLS) and related deposition techniques at the region between the collector elements. In this embodiment, a catalyst 128 such as Au for Si VLS growth may be deposited as seen in FIG. 7. In the embodiment shown in FIG. 7, the region between the collector elements can include a doped poly-Si layer 124 and a counter doped, undoped or both VLS Si layer(s) 126. Deposition of the catalyst 128 may be accomplished with any of the standard techniques such as physical vapor deposition and chemical vapor deposition, electro-chemical deposition or self-assembly. The catalyst 128 may be placed directly on the substrate 114, if the collector structure 110 is to also function as the electrode, or the catalyst 128 may be positioned on the conductor 112. Self-assembly by tethering such as by the linking of catalyst Au particles by theiol bonds to the conductor may be employed with the conductor present The substrate 114 with the collector structure 110 and VSL catalyst layer 128 on it is then placed in a VLS reactor. A silicon precursor such as silane is introduced (at T˜450-550° C. for Au as the catalyst) and the Si precursor breaks down resulting in Si building up in a liquid phase Au/Si alloy in the Au film. Then Si is expelled as the Si concentration exceeds a critical level resulting in crystalline Si growing in the inter-collection element regions. The catalyst (e.g., Au) 128 may then be etched off the crystalline Si outer surface as needed. Since this material can be of high crystallinity, its collection length and absorption lengths can at least be those of poly-Si. These lengths determine the dimensions C and A of the collector structure 110 utilized.

In this VLS absorber growth approach, the catalyst 128 may be positioned with the collector elements present. If desired, the catalyst 128 may be kept off the top surfaces of the collector elements by means such as masking Alternatively, the catalyst 128 may be positioned before the collector elements are present. In this embodiment, the catalyst 128 is deposited using standard approaches with the requisite pattern needed to accommodate the collector structure 110 to be used. This pattern may be generated using approaches comprising block-co-polymer, stamping, imprinting, or beam or optical lithography methods and lift-off and/or etching. After VLS growth, the collector may be positioned with the absorber regions dictating the collector pattern by, for example, using deposition. Lift-off and/or etching may be used also.

The fabrication of a solar cell using a collector structure 110 (and corresponding collector elements) such as that seen in FIGS. 3-5 may make use of a compound semiconductor as the active material positioned among the collector elements. In this embodiment, the compound semiconductor can be used as an absorber only or an absorber/collector and may include the addition of organic or inorganic particles or molecules. Techniques for depositing such thin films are well known and include VLS-type approaches similar to those discussed above including colloidal chemistry techniques.

An organic material or materials can be directly disposed as the active material positioned between collector elements by a variety of physical and chemical methods. Included among the physical methods are sublimiation, nebulization and casting. Included among the chemical methods are electrochemical polymerization, vapor-phase reaction, vapor-phase polymerization, surface-initiated polymerization, and surface-terminated polymerization. In the latter approaches, an element or compound may be deposited on a surface and utilized as a reaction initiator. The nature of the association between the initiator and substrate is a chemical bond (ionic or covalent), a weak association such as hydrogen bonding, or dipole-dipole interaction. While the processes described can be used to create the active layer (absorber) between the collector elements, the processes can also be used to form collector elements in the active region, and to form surface layers for the collector elements. These processes can also be directed to take place on a flat substrate for the express purpose of creating collector elements themselves.

In surface initiated approaches to active layer formation, organic molecules are exposed in one approach to the substrate-bound or collector element-bound initiator, initiating a desired chemical reaction. The molecules available for reaction vary in size from that of essentially several atoms to that of macromolecules. The reaction proceeds as long as molecules are present to propagate or until a termination molecule is introduced. The final molecules produced may be highly ordered with a controllable thickness. Vapor-phase polymerization or surface-initiated polymerization may be used.

In surface terminated approaches, a macromolecule is formed in solution under conditions which give the desired physical and chemical properties. The macromolecule is then exposed to the surface containing the termination group. The termination group located on the surface ends the propagation of the macromolecules while simultaneously anchoring them to the surface. This approach allows for the use of typical solution polymerization techniques, while maintaining control of surface coverage and density.

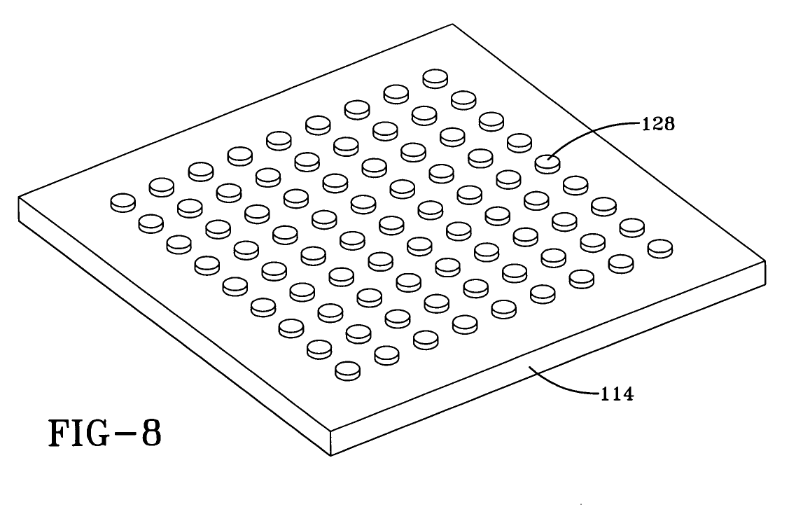

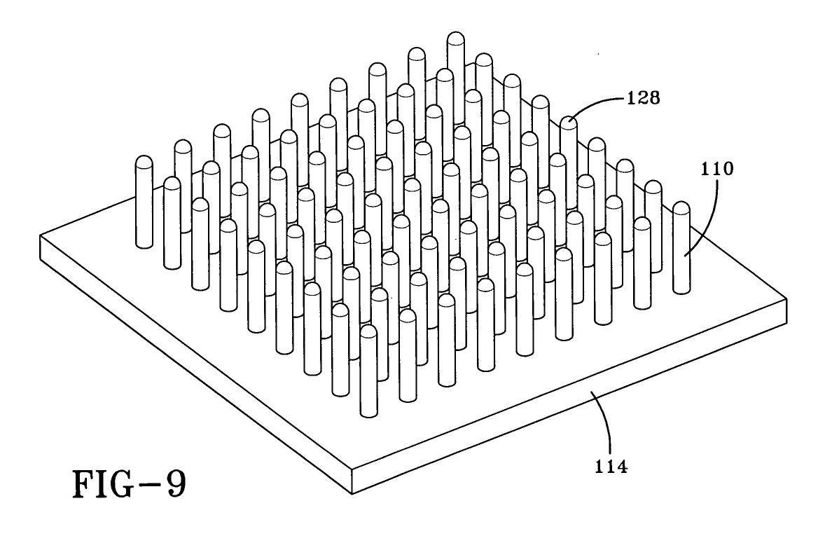

Crystalline or amorphous silicon or other inorganic semiconductors can also be used as the material forming the collector structure 110. For example, thin film crystalline silicon may be used and doped n or p-typed, as desired. To form the collector structure 110 (e.g., column, fin, honeycomb), the VLS approach may be used with the necessary patterned catalyst 128. A patterned catalyst 128 suitable for column growth is shown in FIG. 8. Such a patterned catalyst may be achieved, for example, by printing gold bearing layers using known printing techniques. Such gold bearing layers may be composed of materials such as Au bearing ink, for example, or functionalized Au nanoparticles designed to adhere to the substrate on contact. With this patterned catalyst seen in FIG. 8 and with the VLS approach, columns, in this example, may be grown as seen in FIG. 9. The catalyst positioned on top of the elements (and any of the walls) may then be removed by straightforward etching. Active material is then positioned among the collector elements. A variety of catalysts may also be used and other semiconductors, as well as metals, may be grown for the collector element function. In general, catalyst deposition and patterning may be attained using positioning techniques comprising stamping, electro-static printing, printing and dip pen or by using other standard physical and vapor phase deposition techniques or electro-chemical deposition with etching or lift off patterning employing block-co-polymer use, imprinting, or beam or optical lithography.

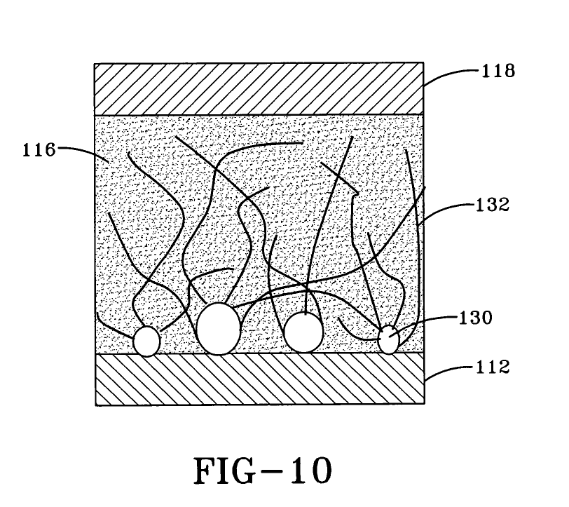

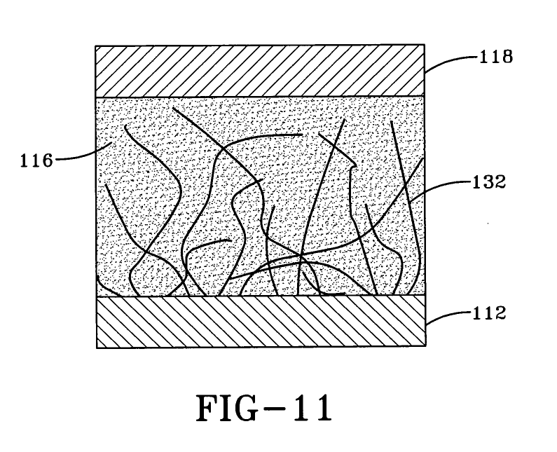

Depending on the details of the catalyst type and shape and whether it is composed of particles (FIG. 10) or is a discontinuous film (FIG. 11) the degree to which the collector elements are perpendicular to the substrate may vary. In the structure of FIGS. 10 and 11, which specifically show this situation for the case of nano-elements 132, light may enter into the device through the top conductor 118 or the bottom conductor 112. One conductor, e.g., the bottom conductor 112 in FIG. 10, has nano-elements 132, e.g., nanowires or nanotubes, electrically connected to the surface-covering conductor and extending from the conductor to penetrate into an active layer 116. The other conductor, e.g., the top conductor 118 in FIG. 10, does not necessarily have nano-elements, which is the case shown in FIG. 10. The nano-elements 132 are intended to aid in photogenerated carrier collection. If the bottom conductor 112 in FIG. 10 is the anode, then the nano-elements 132 are designed to collect holes (whether free holes collected from the active layer, holes produced by breaking up excitons at the elements' surface, or some combination thereof). If the bottom conductor 112 in FIG. 10 is the cathode, then the nano-elements 132 are designed to collect electrons (whether free electrons collected from the active layer, electrons produced by breaking up excitons at the elements' surface, or some combination thereof). The material composition of the nano-elements 132 is selected to enhance the mobility of the collected carrier, to provide the requisite workfunction difference (with the top conductor 118) to aid in setting up the built-in collecting electric field, or to have band steps (off-sets) to aid in collection, or some combination thereof. The photogenerated entities to be collected are created in the active material, which may be an organic, inorganic, or combination materials system positioned between the conductors 112, 118 and among the penetrating nano-elements 132. The active layer 116 may contain semiconductors, dyes, quantum dots, metal nanoparticles, or combinations thereof. The active layer material can be a light absorber or mixture of the absorber and generated-charge collector or collectors. Active layer materials systems may be produced by various growth and deposition approaches including chemical and electrochemical means, chemical vapor deposition, or physical vapor deposition. The active layer materials systems may also contain electrolytes.

The structures of FIGS. 10 and 11 can be positioned and produced using catalytic approaches. The nano-particles 130 seen in FIG. 10 act as a catalyst for the growth of the nano-elements 132 penetrating the active layer 116. The nano-particles 130 may or may not remain after the nano-element 132 growth. The metal nano-particles 130 can be designed to remain after growth to be used to generate plasmons to enhance light absorption on the active layer 116.

The nano-elements 132 may be grown first and then the active layer 116 grown or deposited around the nano-elements 132. For example, nano-particle/element (nano-wire or nano-tube) systems can be gold nano-particles for the growth of silicon nano-wires and iron or iron based nano-particles for the growth of carbon nano-tubes and nano-filaments. As a specific example, in the case of Si, the silicon nano-wires may be grown on the bottom electrode by first depositing the catalyst nano-particles by spinning, spraying, stamping, printing, or other dispersive techniques including the use of bacteria. Subsequently, the coated bottom conductor is placed in a growth chamber for Si nano-wire growth, which may be accomplished, for example, by the vapor-liquid-solid (VLS) technique using low pressure chemical vapor deposition (LPCVD) with a Si precursor gas such as silane, di-chloro-silane, etc., perhaps with a dopant gas as for nano-wire doping during growth. The density and directions of the resulting nano-wires can be adjusted using catalyst size, type, and arrangement and deposition parameters. The same catalytic approaches may be used for the growth of other semiconductor nano-structures such as C, ZnO, GaN, and CdTe nanotubes and nanowires.

In the case of carbon, the carbon nano-channels or nano-filaments may be grown on the bottom conductor by first depositing the catalyst nano-particles by spinning, spraying, or other dispersive techniques. Subsequently the coated bottom conductor is placed in a growth chamber for carbon nano-tube or nano-filament (nanowire) growth (e.g., by using a carbon precursor gas and low pressure chemical vapor deposition (LPCVD)).

Depending on the catalyst nano-particle size and element growth conditions, the catalyst nano-particles 130 seen in FIG. 10 may actually disappear from the bottom conductor 112 during growth due to their riding on the top of the growing nano-element 132 or their being incorporated into the growing nano-element 132. The resulting nano-wires or nano-channels produced from this catalyst driven deposition may have a random orientation as seen in FIG. 10 or be more ordered perpendicularly to the bottom conductor 112, depending on catalyst nano-particle size and growth conditions. In either case, the resulting nano-elements 132 collect laterally at least over some part of their penetration into the active layer 116.

As an alternative to positioning catalyst nano-particles 130 on the bottom conductor 112 or top conductor 118, a discontinuous film of the catalyst material can be deposited by chemical vapor or physical vapor deposition or can be produced by positioning techniques such as dip pen and stamping. For example, physically deposited metal films with a thickness less than about 10 nm are generally discontinuous thereby effectively giving a surface covered by nano-islands which can serve as the catalysts for the required nano-wire or nano-tube growth.

The lateral collection approach can use elements constituting opposing electrodes as shown in FIG. 12. The lateral collection concept does not require that the cathode and anode be arranged as seen in FIGS. 1-7, 10 and 11, i.e., one electrode need not be on top of the other but, instead, the two electrodes can face each other laterally. In the lateral electrode arrangement, the collection of the photogenerated entity (excitions and/or free holes and electrons) is essentially entirely done in a lateral fashion, i.e., at essentially ninety degrees to the absorption length direction. The term “vertical collection length,” discussed previously, now refers to a lateral length. Further, the absorption length and the vertical collection length no longer have any bearing on one another. For example, in the embodiment of FIG. 10, the collection of only one carrier, usually that with the poorer mobility, is done at an angle to the absorption length direction. In the lateral collection by lateral arrangement of both electrodes approach, the two electrodes (anode and cathode) are each formed, in general, of an independent array of nano- and/or micro-scale elements.

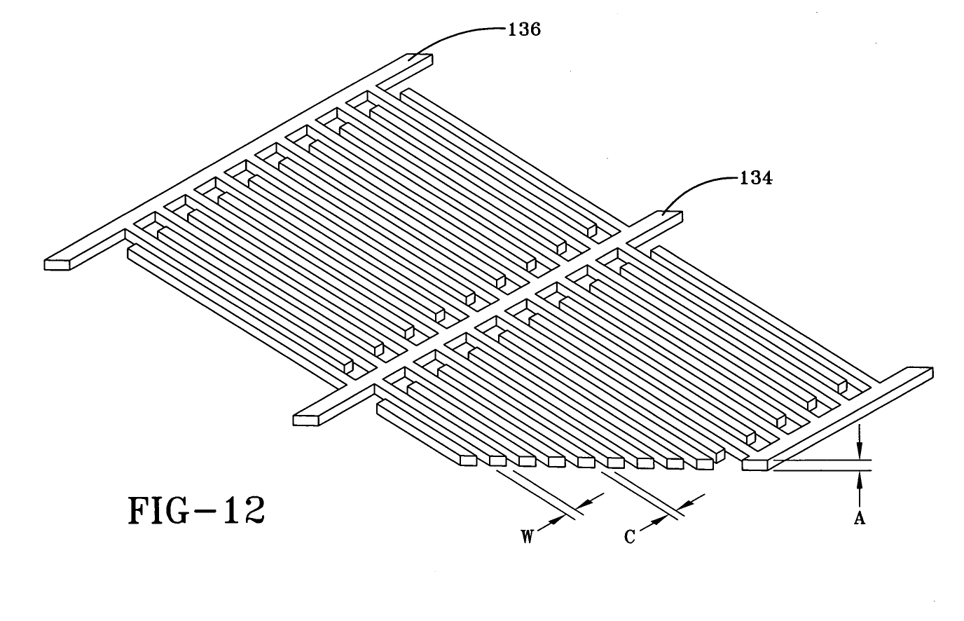

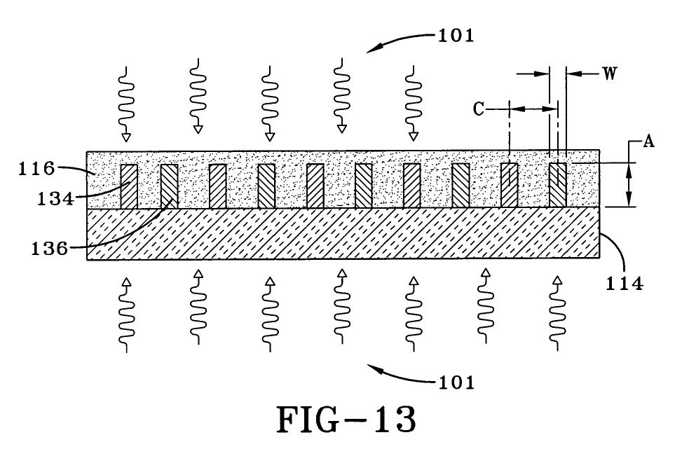

For the lateral collection by lateral arrangement of both electrodes approach, either the fin structure of FIGS. 12 and 13 or other similar electrode structures can be used. In the embodiment of FIGS. 12 and 13, which may have nano-scale or micro-scale array spacing, the arrangement is such that all components of the first electrode 134 and all components of the second electrode 136 sit on an insulator (not shown) and are electrically isolated from each other with one electrode serving as the anode collecting photogenerated holes (whether produced directly, by excition decomposition, or both) and the other electrode serving as the cathode collecting photogenerated electrons (whether produced directly, by excition decomposition, or both). The photogenerated entities are created in the active material, which may be an organic, inorganic, or combination materials system positioned among the electrodes 134, 136. The active layer may contain semiconductors, dyes, quantum dots, metal nanoparticles, or combinations thereof. The active layer material can be a light absorber or mixture of the absorber and generated-charge collector (separator) materials. The active layer materials systems may be produced by various growth and deposition approaches, as noted earlier, including chemical and electrochemical means, chemical vapor deposition, or physical vapor deposition, including nebulization. The active layer materials systems may also contain electrolytes. The elements of the first electrode 134 may be arranged in a hierarchy as seen in FIG. 12 in which smaller sized elements connect to larger elements to reduce series resistance. The same may be the case for the second electrode 136. In cross-section, the example structure of FIG. 12 would appear as seen in FIG. 13. The active layer 116 may or may not be thicker than the height A of the first electrode 134 and the second electrode 136 structures. The dimension A is preferably equal to the active material absorption length. In addition, the width W of both the first electrode 134 and the second electrode 136 structures should be as small as possible, preferably in the nano-scale range but consistent with series resistance loss and manufacturing considerations. The arrangement of the electrodes 134, 136 as shown in FIGS. 12 and 13 requires no bottom nor top electrode on the active layer 116. In addition, light 101 may enter either through the top or bottom side. A reflector may be positioned at one side. The array separation C between the neighboring elements is of the order of one active material collection length or less. The electrode elements themselves may, in addition to collecting photogenerated entities, (1) be an absorber, (2) enhance light reflection and trapping, (3) be used to attach quantum dots/nano-particles, monolayers, or other materials to enhance performance, and (4) be the source for plasmons for interaction with the absorption process. This embodiment may be used in light generating applications. In the light generating application, the active layer 116 is not absorbing light but producing it. It follows that the electrodes 134, 136 in such a situation are not collecting carriers but are injecting them. As noted earlier, these light emitting structures are essentially operated in the opposite sense as a photovoltaic device and the materials selection is dictated by that necessity.

The anode and cathode of lateral collection photovoltaic structures such as that shown in FIGS. 12 and 13 can be made of materials that create a built-in electric field (or, equivalently, a built-in potential) directed between them, across the active material. The field direction is substantially perpendicular to the absorption length direction. Creating the electric field necessitates that the anode and cathode be pairs such as a high workfunction metal and a low workfunction metal, a p-type semiconductor and an n-type semiconductor, a high workfunction metal and an n-type semiconductor, or a low workfunction metal and a p-type semiconductor. The electrodes 134, 136 may be treated (e.g., with a plasma) or coated with films or with monolayers using self-assembly to adjust the workfunctions. Additionally, the electrode materials may also have energy band steps (off-sets) that act to block holes (at the cathode) or block electrons (at the anode) to assist in carrier collection.

Lateral anode and cathode electrode arrangements, such as that seen in FIGS. 12 and 13, may be fabricated using well known lithography techniques such as photo and e- and ion-beam lithography combined with well established etching and/or lift-off techniques. They also may be fabricated using techniques such as block co-polymer patterning, imprint and step and flash lithography combined with the well established etching or lift-off techniques. Further, they may be fabricated by other techniques such as dip-pen processing, ink jet printing, electrostatic printing and stamping which require no etching nor lift-off. Lateral anode and cathode electrode arrangements, such as that seen in FIGS. 12 and 13, may also be fabricated by laser writing of the pattern in a material that reacts upon photon impingement to form the patterned electrode layout. This may be done sequentially for the first electrode 134 and then the second electrode 136. To obtain the differing materials systems required to create the desired built-in electric field and band steps, the first electrode 134 may be first positioned and then the second electrode 136, using the aforementioned approaches. Alternatively, both sets of electrode elements can be made of the same material and then one electrode is electro-plated with a different material for field and band step creation. This is easily done since each set has an independent connection to the outside world. In general, the materials that are patterned and used to make the first electrode 134 and the second electrode 136 can be grown or deposited.

Lateral anode and cathode electrode arrangements, such as that shown in FIGS. 12 and 13, may also be entirely fabricated using electro-less and/or electrode driven plating such as electro-chemical deposition. The plating can be done, for example, by the positioning of a first conducting pattern for the electro-chemical growth of the first electrode 134 using a first solution and by the positioning of a second conducting pattern for the electro-chemical growth of the second electrode 136 using a second solution. Two electro-chemical deposition solutions are used to attain two different materials, as explained, for the anode and cathode. The patterns should be positioned on the insulating substrate in the design required to obtain the electro-chemical deposition of the necessary laterally disposed anode and cathode. For example, in the case of the structure of FIGS. 12 and 13, one pattern would be on the substrate to the form of the first electrode 134 and another electrically isolated pad would be on the substrate to the form of the second electrode 136. Such electrode precursor patterning can be done with optical, beam, and imprinting lithography combined with etching and/or lift-off. Electrode precursor patterning may also be accomplished by techniques such as direct patterning wherein the pattern material is applied in the prescribed pattern by various techniques including stamping, dip pen, printing, electrostatic printing, or ink jet printing. These patterns (e.g., those in the pattern of the example of FIGS. 12 and 13) may then be sequentially electrically biased to electro-chemically deposit an electrode of one material and a second electrode of another material. That is, sequential biasing of the first pattern with the first solution applied to the substrate may be used to obtain the electro-chemical deposition of the first electrode 134 and sequential biasing of the second pattern with the second solution applied to the substrate may be used to obtain the electro-chemical deposition of the second electrode 136.

Electro-chemical deposition may also be used in an alternative manner to obtain the lateral anode and cathode electrode arrangements, such as that seen in FIGS. 12 and 13. A template containing a recessed first material electrode and a second material electrode, patterned, using the techniques discussed earlier, in the arrangement needed for the cathode and anode of the photovoltaic device, is applied to the substrate with an electro-chemical deposition solution present. The substrate is conducting. By applying an electrical bias between the first material electrode pattern in the template and the substrate, material forming into the first electrode 134 is thereby deposited on the substrate guided by the template. By sequentially applying an electrical bias between the second material electrode pattern in the template and the substrate, material forming into the second electrode 136 is thereby deposited on the substrate guided by the template. This template can then be stepped and reused. The initial conducting film on the substrate is etched away or converted to an insulator, as needed, to prevent shorting. The concept here uses two different electrodes in the template (of the first and second materials, respectively) and sequential biasing to be able to deposit the two different materials needed for the anode and cathode of the lateral collection layout by lateral arrangement of both electrodes in the template. The technique here also removes or converts the initial thin film covering the surface.

Lateral anode and cathode electrode arrangements, as shown in FIGS. 12 and 13, may be also fabricated using catalyst-controlled growth. Catalyst controlled growth can be performed, for example, by the positioning of catalyst A for the growth of the first electrode 134 and the positioning of catalyst B for the growth of the second electrode 136. These catalysts can be in the pattern required to obtain the necessary laterally disposed anode and cathode. For example, in the case of the structure of FIGS. 12 and 13, catalyst A would be patterned on the substrate in the form of the first electrode 134 and catalyst B would be patterned on the substrate in the form of the second electrode 136. Such catalyst patterning can be done as described above. Included techniques would be optical, beam, and imprinting lithography combined with etching and/or lift-off and applied to grown or deposited catalyst materials. It can be done by laser writing of the pattern in a material which reacts upon photon impingement to form the catalyst (or to directly form the patterned electrode layout). Obtaining patterned catalyst A and catalyst B may be done sequentially. After catalyst application to the substrate, first and second electrodes 134, 136 are grown using their respective catalysts. Electro-chemical and chemical processes (e.g., VLS) can also be used.

The application and patterning of catalyst A and of catalyst B can also be done with positioning techniques such as stamping, dip pen, electro-static printing or ink jet printing of catalyst “inks” Such inks may contain particles, self-assembling molecules, layers, or materials, or both which contain the catalyst. Obtaining patterned catalyst A and catalyst B by stamping, dip pen, or ink jet printing can be done by sequential steps with appropriate considerations for alignment. In the case of stamping, an alternative is to simultaneously stamp catalyst A and catalyst B onto a substrate. The latter stamping approach may be accomplished for the structure of FIGS. 12 and 13 by (1) picking up both inks simultaneously by applying the stamp to ink-containing troughs in the pattern of FIGS. 12 and 13 or by (2) applying the inks sequentially to the stamp using dip pen, ink jet, or similar techniques. After catalyst application to the substrate, first and second electrodes 134, 136 are grown using their respective catalysts. Chemical processes (e.g., VLS) are used. The resulting the first electrode and second electrode element cross-sections can then approach the rectangles of FIG. 13. The cross-sections of the first and second electrode elements may be quite close to such overall rectangular shape if the grown first and second electrodes 134, 136 are, for example, closely packed arrays of high aspect ratio nano-particles such as Si nanowire elements (which may be doped during growth) and carbon nanotube elements grown catalytically from the patterned catalysts A and B.

For all the various approaches to producing the lateral collection electrode structures, the organic or inorganic absorber containing active material placement can be achieved in a number of ways, as discussed earlier. Included are the various physical and chemical vapor deposition techniques. Specifically included are nebulization, spraying and spin-on techniques. Materials such as ZnO, GaN, CdSe, PbS, and related semiconductors can be produced using well-known techniques from colloidal chemistry thereby growing the material between first and second electrodes 134, 136 in situ. Inorganic semiconductor materials such as a-Si:H or polycrystalline Si can be vacuum deposited and used, as is. In the case of amorphous materials such as a-Si, a-Ge, etc., SPC including its variant metal induces solid phase crystallization (MISPC), can be used in situ to convert such deposited amorphous semiconductors into crystalline material. Support materials, such as hole conductive layers, electron conductive layers, electrode surface modification, or layers to initiate or provide attachment points for surface modification can be disposed between any layer or on electrode elements.

The anode and cathode of lateral collection structures shown in FIGS. 12 and 13 may themselves also serve as catalysts for active layer formation processes in techniques such as chemical growth or metal induced solid phase crystallization. The anode, the cathode, or both may play the catalyst role. For example, if silicon is the active layer 116, it may be grown in the region between the anode and cathode using VLS chemical growth with one of the electrodes being the VLS catalyst. Depending on the electrode material, and, therefore on the catalyst being used, crystalline Si can be grown this way at temperatures between 300 and 600° C. In the case of SPC of silicon, for example, deposited a-Si can be crystallized into the active layer with MISPC done with various time-temperature annealing procedures using, for example, Ni as one of the electrodes and as the metal enhancing the SPC process.

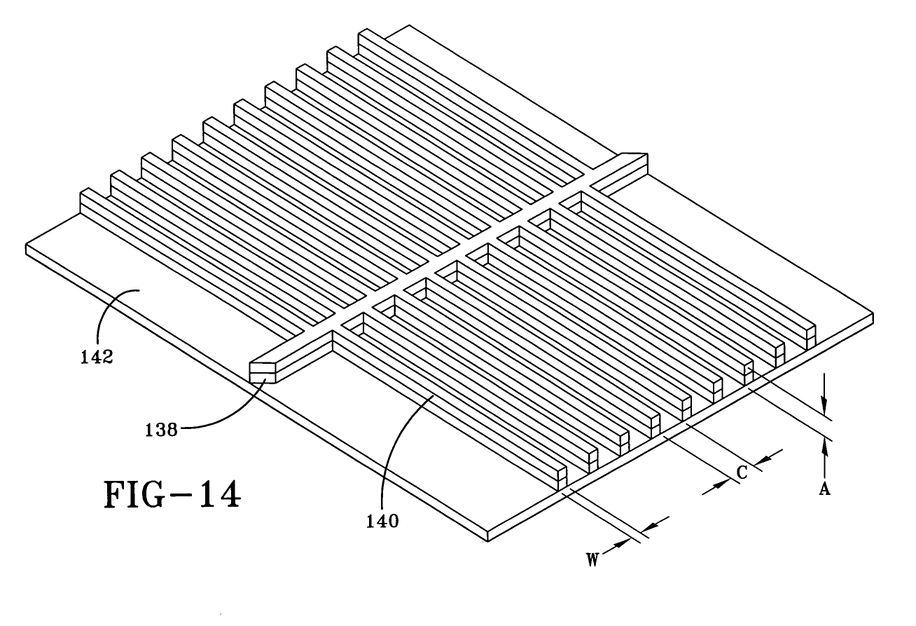

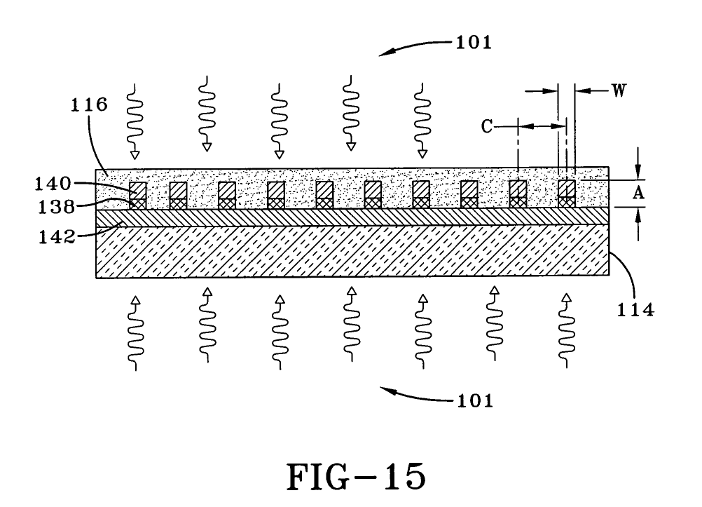

In the Lateral Collection by Composite Electrodes carrier collection approach, at least one electrode (anode or cathode) is a composite structure and first electrode 140 (anode or cathode) and second electrode 142 (cathode or anode) are arranged as depicted in FIGS. 14-17 with the active layer material positioned, as shown. The structures of FIGS. 14-17 are top electrode over bottom electrode configurations as opposed to the lateral electrode configurations given in the example of FIGS. 12 and 13. In the version shown in FIGS. 14 and 15, first electrode 140 is a composite structure and the top of each of element of first electrode 140 is the conducting first electrode material. The conducting first electrode material is seen to be electrically isolated by the insulator 138 in each component from second electrode 142 that resides on the substrate. First electrode and second electrode materials are chosen with the concerns of selecting materials to create a built-in electric field for photogenerated charge carrier collection. Creating this field necessitates that the anode and cathode pairs can be a high workfunction metal and a low workfunction metal, a p-type semiconductor and an n-type semiconductor, a high workfunction metal and an n-type semiconductor, or a low workfunction metal and a p-type semiconductor. The first and second electrodes 140, 142 may be treated (e.g., with a plasma) or coated with films or with monolayers using self assembly to adjust the workfunctions. The first and second electrode materials also may be chosen to augment field collection by the use of band edge off-sets (steps), which can be particularly useful in exciton decomposition. Collection in this structure will have both lateral and perpendicular (i.e., parallel to the absorption length) aspects. The insulator 138 required in the approach of FIGS. 14 and 15 may be produced by techniques comprising deposition, electrochemical reactions, and growth including oxidation or nitridation.

In the embodiment shown in FIGS. 16 and 17, each element is a composite structure containing first electrode and second electrode components separated by an insulator 138. The two electrodes 140, 142 are then independently contacted (not shown) for connecting to an external circuit. First electrode and second electrode materials are chosen with the usual concerns of selecting materials to create a built-in electric field for photogenerated entity collection. The first and second electrode materials also may be chosen to augment collection by the use of band edge off-sets (steps). The net result of this structure is that both photogenerated carriers can be collected laterally and vertically. The insulator 138 required in the approach of FIGS. 16 and 17 may be produced by techniques such as deposition, electrochemical reaction, or growth including oxidation or nitridation.

The approaches seen in FIGS. 14-17 offer the alternative of not having to sequentially create the lateral first electrode 134 and second electrode 136 structures needed in FIGS. 12 and 13. The components of FIGS. 14-17 are patterned and fabricated using all the various possibilities discussed earlier including those for the embodiment of FIGS. 12 and 13. The dimension A in the composite electrodes of FIGS. 14-17 is preferably equal to the active material absorption length. In addition, the element width W in FIGS. 14-17 should be as small as possible, if the element material is not being used as an absorber, preferably in the nano-scale range but consistent with series resistance loss and manufacturing considerations.

FIG. 18 shows the cross-section of a photovoltaic device where the electrode elements are shown located in the active material. The photovoltaic device 160 includes a first conductor or electrode 150 that can be a non-patterned (non-structured) electrode that is opposite a second electrode 152 that includes an array of collector elements. The second electrode 152 can include the structured collector elements (e.g., columns, nanotubes, nanowires, fins, honeycombs or even molecular wires) for improving photogenerated entity (excitons and/or electrons or holes) collection. Positioned adjacent the second electrode 152 is an active layer 154 and positioned adjacent to the first electrode 150 is a collection material or hole transporting layer (HTL) 156 for augmenting, in this embodiment, hole collection. Between the first and second electrodes 150, 152 can be an insulator or separator material 158. This structure can have been formed by some processing combination comprising etching, growth desposition, lift off or impressing (inlaying).

In this embodiment, the insulator or separator material 158 is present to cap the collector elements of the second electrode 152 to prevent shorting of the device as a result of the second electrode 152 coming into contact with the first electrode 150. The array spacing and elements of second electrode 152 may be on the micro- and/or nano-scale. The use of such insulating cap material can be particularly useful when pressing or imprinting (in laying) the second electrode 152 into the active layer 116.

During fabrication of a photovoltaic device using an impressing technique, first electrode 150 can have the HTL 56 and then the active layer 154 disposed directly on the first electrode 150. The second electrode 152 is then pressed into the active material 154. When doing so, it is possible to short the photovoltaic device by having at least one of the collector elements of the second electrode 152 press through both the active layer 154 to the hole collector material in this example (e.g., the HTL) 156 or even to the first electrode 150. If the second electrode 152 penetrates through the active layer 154 and comes in close proximity with the collector material 156 or first electrode 150, it is possible that the photovoltaic device is shorted.

To prevent the formation of such a shorting situation in a photovoltaic device fabricated by an impressing technique, an insulator or separator material 158 is placed as a cap on the collector elements of the second electrode 152 to prevent the second electrode 152 from coming in contact with the collector material 156, the first electrode 150, or both.

First and second electrodes 150, 152 can be composed of a conductive or semiconductive material. Common materials that may be used for first and second electrodes 150, 152 are, but not limited to, indium tin oxide, aluminum, gold, carbon nanotubes, and lithium fluoride.

The active layer 154 is composed of an absorber and a charge carrier (i.e., a separation material) or any combination thereof. The active layer 154 may include semiconductors, dyes, quantum dots, metal nanoparticles, conductive polymers, conductive small molecules, or combinations thereof. The collector material 156 may be an HTL (typically poly(3,4-ethylenedioxythiophene):poly(styrene sulfonate) (PEDOT:PSS) but may include doped poly(aniline), undoped poly(aniline)) or may be absent completely.

In uses of this cap approach, the insulator 158 can be composed of any non-conductive material that can prevent a short between second electrode 152 and the HTL 156 or the first electrode 150. Typical materials that may be employed may include but are not limited to SiO₂, poly(styrene), or poly(methyl methacrylate). The thickness of the insulation layer or insulator 158 should be thicker than the thickness of the collector material 156, so that no electrical contact is made between the conducting part of the second electrode 152 and the collector material 156 and the first electrode 150. If the collector material 156 is not present, then the thickness of the insulator 158 must be that required for insulator integrity and the prevention of any electrical contact between the first and second electrodes 150 and 152.

The second electrode/insulator cap structure can be fabricated through standard lithographic techniques. The second electrode/insulator structure can be fabricated by a number of other techniques including through an evaporation process into an e-beam or block copolymer mask. The second electrode/insulator structure can also be produced by electro-chemical processes. The second electrode/insulator structure may also be fabricated through dry etching through a hard mask. The insulator structure may be used as a hard mask for the etching of the second electrode structure—then left in place to act as the insulator cap structure. The thickness of the insulation layer 158 can be between ideally about 10 to 20 nm thicker than the thickness of the collector (e.g., HTL) material 156, if present. If the collector material 156 is not present, then thickness of the insulator can be in the range of about 5 to 20 nm, as needed for insulator integrity.

As discussed, solid phase crystallization (SPC) may be used to render a semiconductor material into a crystalline phase (nano-crystalline, polycrystalline, or single crystal). SPC may be used with the electrode configurations of the present invention. In particular, SPC may be used when the electrode configuration uses a fin-like set of electrode elements (e.g., FIG. 5) and a planar counter electrode positioned either above or below the fin structure. SPC may also be used when alternating anode and cathode electrode elements are employed such as in FIGS. 12 and 13. When non-crystalline (e.g., amorphous) silicon, its alloys, or other semiconductor materials are employed as the inter-electrode element active layer material, metal induced SPC using metals, such as including nickel, palladium, and aluminum, or silicon induced solid phase crystallization (SISPC) may be used to achieve SPC. In the embodiments to be discussed, reference is made to silicon materials, SPC catalysts such as Ni, low work function materials such as Al, and encapsulating layers such as Si3N4 as exemplary materials. However, other semiconductors, SPC catalyst metals, low work function materials, and encapsulating materials may be used.

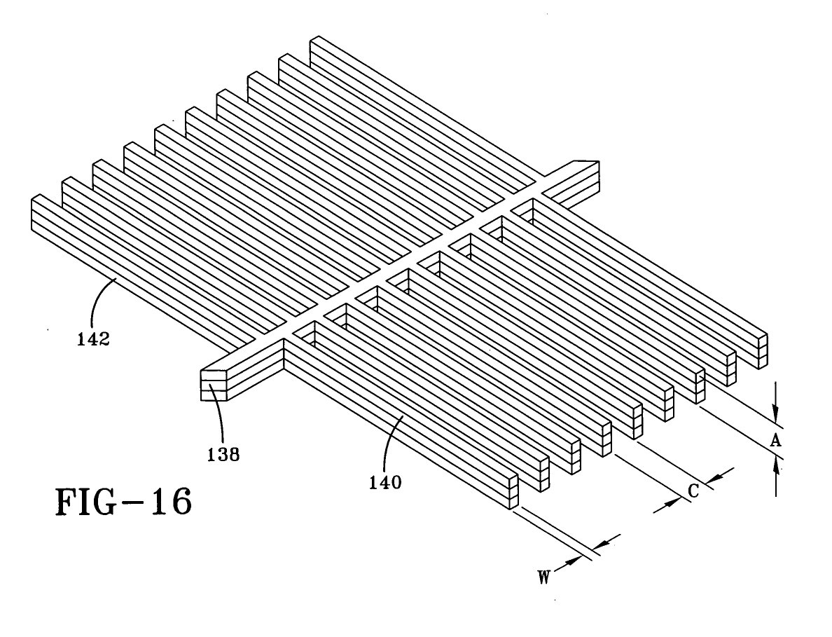

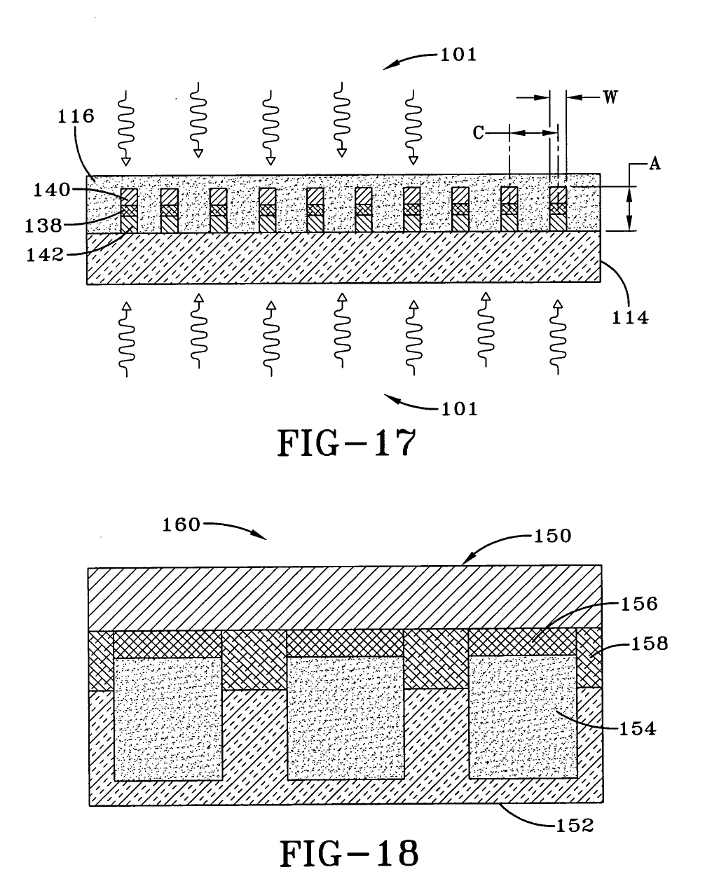

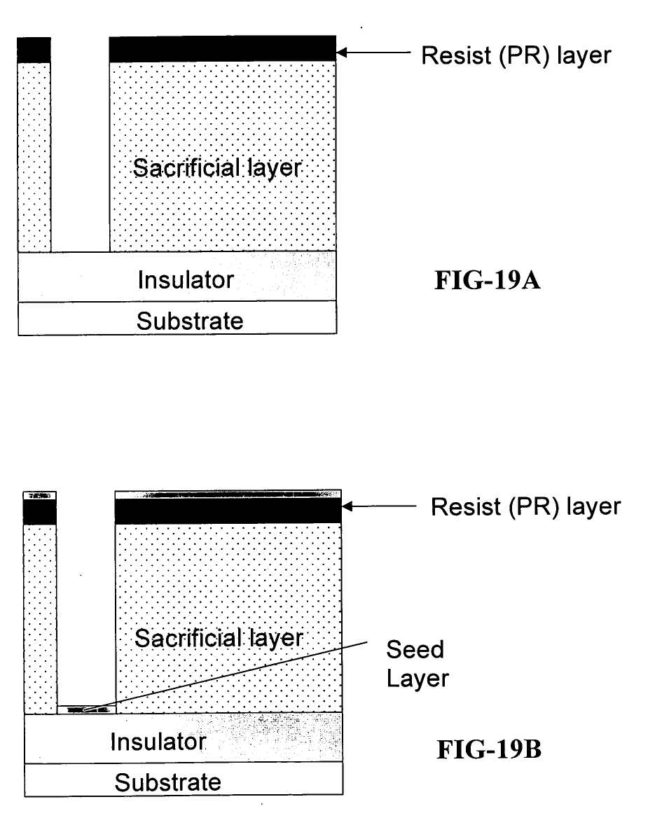

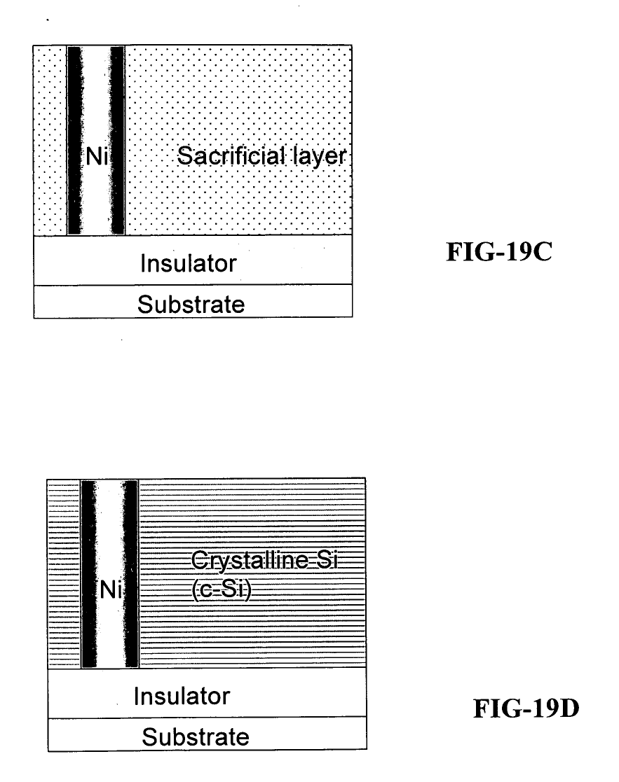

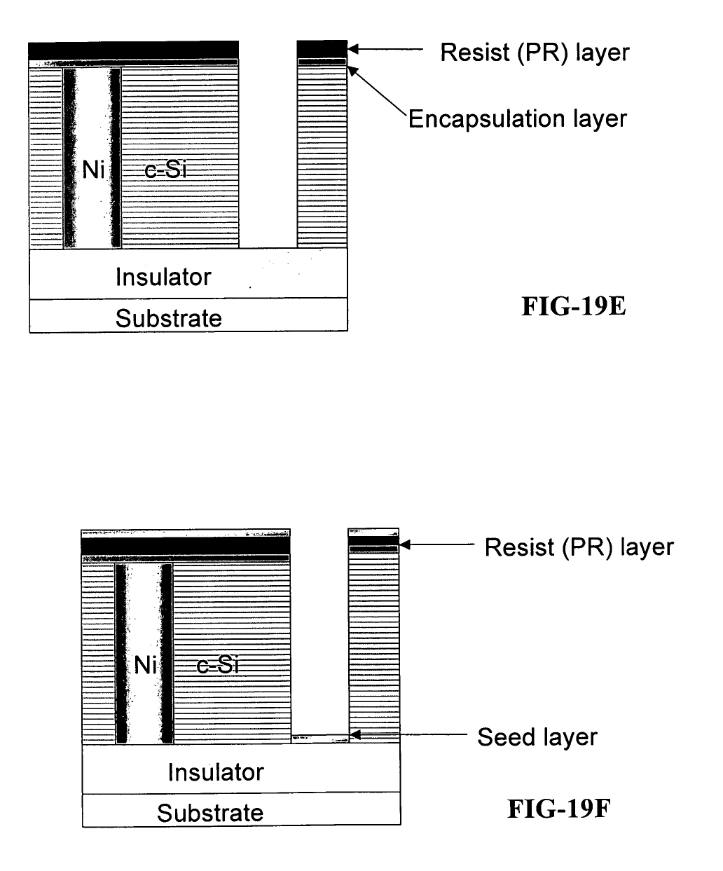

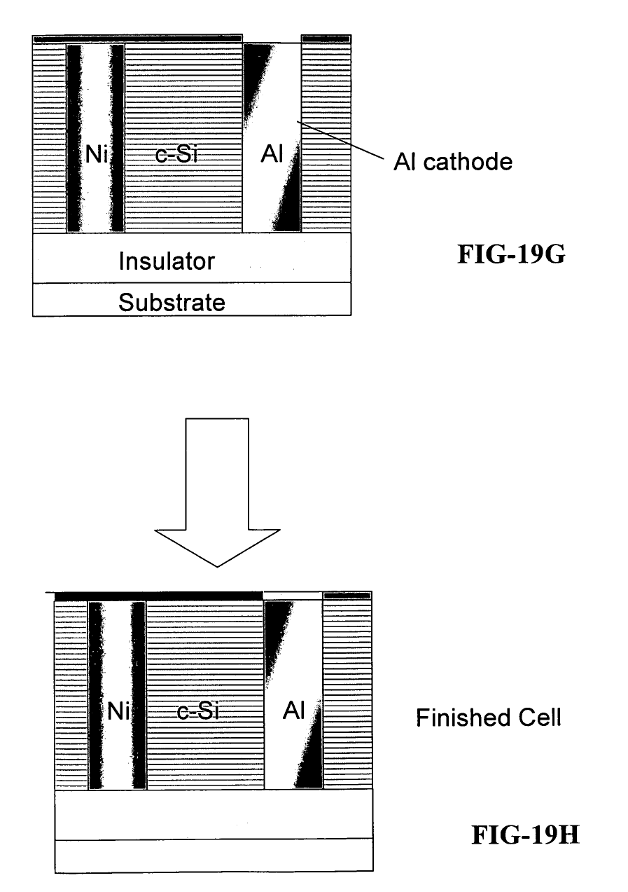

When metal induced SPC is employed, exemplary structures such as that seen in FIGS. 19A-19H may be utilized or generated. The structure is built on a substrate, e.g., glass or metal, on which an insulator may be disposed, if the substrate is a metal. A textured metal layer may be disposed beneath this insulator for light reflection, plasmonic generation, or both. Alternatively, if a metal substrate is used, it may be directly textured. Next, a sacrificial layer, which may have a thickness of about 2 to 10 microns, is disposed onto the substrate (i.e., on the insulator, if present). A pattern is positioned in the sacrificial layer or a resist layer above the sacrificial layer or both using a lithography (pattern transferring) processing, which may include involvement of conventional optical lithography, holography, stamping, or imprinting. If the latter two approaches are used, they may be done in a role-to-role format. The pattern in the sacrificial layer and/or the resist is, transferred utilizing standard techniques, such as etching, into the sacrificial layer down to the insulator (or substrate), creating “trenches” at multiple equivalent positions (see FIG. 19A). The metal that is to be the catalyst for metal induced SPC, and to serve as an anode or cathode element, is disposed so as to fill the trench in the sacrificial layer. The filling of the trench with the metal may be done by a variety of techniques including deposition and lift-off, ink jet printing and lift-off, or deposition of a seed layer followed by electro-deposition (see FIG. 19B). These steps can be done at multiple equivalent positions across the structure. To reduce contamination issues, the seed layer should be the same metal as will be used for the metal induced SPC. FIG. 19C shows the use of a nickel (Ni) element for the metal induced SPC of a-Si. The nickel element shown in FIG. 19C can, because of its high work function, also serve as an anode element of the structure. After formation of the metal element, i.e., the nickel element shown in FIG. 19C, the sacrificial layer is removed, the amorphous semiconductor to be crystallized is deposited, and SPC is undertaken. Metal induced SPC of a-Si may be done by rapid thermal annealing (RTA) with a variety of light spectra or by using furnace annealing to obtain crystalline Si (c-Si). FIG. 19D illustrates the structure after completion of the annealing process.

Once the elements of one electrode are in place, e.g., the anode elements as shown FIG. 19D, the counter electrode has to be positioned. The counter electrode could be a plane such as the plane electrode above the electrode elements seen in FIG. 6 (which would have the same general features for c-Si). The counter electrode could also be composed of elements spaced between the already positioned elements such as that seen in FIGS. 12 and 13. In pursuing the alternating electrode elements configuration of FIGS. 12 and 13, the steps as shown in FIGS. 19E-19G, or their equivalents, may be followed. Lithography (pattern transfer) may be used to define and etch trenches into the c-Si for the counter-electrode elements. Such pattern transfer processing may include involvement of conventional optical lithography, holography, stamping, or imprinting, including a role-to-role format. An optional encapsulation layer, e.g. silicon nitride, Si3N4, can be applied on the c-Si and a resist layer can be applied on the encapsulation layer. Since the anode elements have been created using Ni in the example shown in FIG. 19D, a low work function material for these cathode elements in this specific example should be used. The positioning of a low work function material may be done by a variety of means including deposition and lift-off, ink jet printing and lift-off, or deposition of a seed layer as shown in FIG. 19F and electrochemical growth of the material. FIGS. 19F-19H specifically show an example where this low work function material is Al. These steps for positioning of the counter-electrode elements can be done at multiple equivalent positions across the structure. It is to be noted that the actual SPC step may be done before or after the creation of the trenches for the second set of electrode elements. In addition, a variant of this approach can be used in which there is no sacrificial material utilization but, instead, the material to undergo SPC is already present in place of the sacrificial material shown in FIG. 19A.

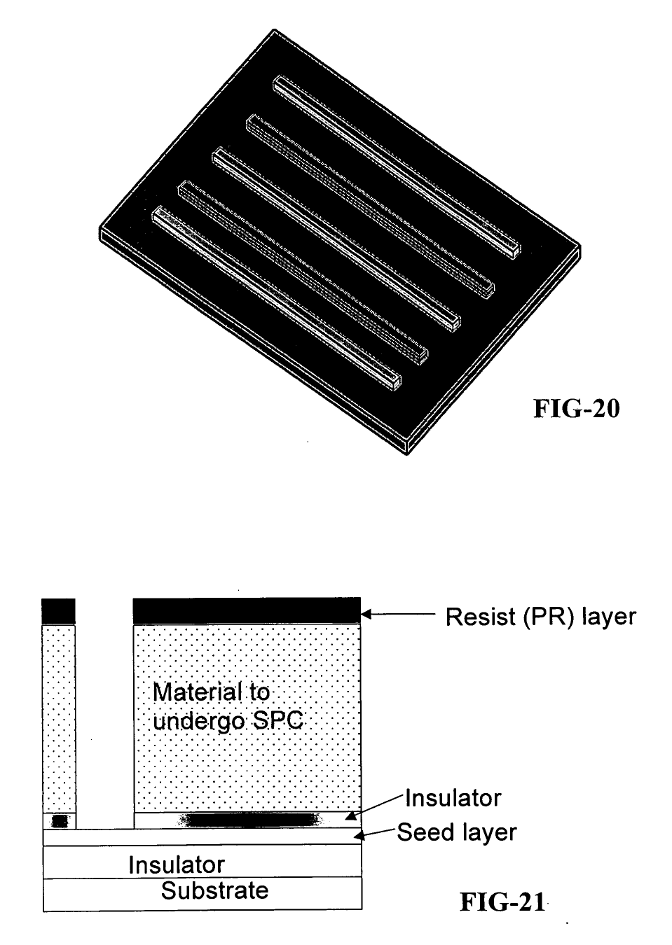

FIG. 19H shows one electrode element/counter-electrode element unit of a final device. FIG. 20 shows all the materials removed from the structure except for the electrode elements and focuses on the resulting array of electrode elements and counter-electrode elements that is present in the structure of FIG. 19H. Using standard interconnection schemes which may be implemented, for example, at the ends of the electrodes, these electrodes may be configured so that a preselected number of units are “wired” in series and in parallel. When series connections are involved, isolation at specific unit boundaries may be necessary which may be accomplished with techniques such as trench etching, laser scribing, or laser ablation.

While FIGS. 19A-19G show a particular set of processing steps, other alternative processing may be used to attain the structure and functionality of the structure of FIG. 19H. For example, in the case of electro-chemical deposition of the first set of electrode elements, the seed layer may be stamped or other wise disposed across the insulator layer and then covered with a second insulator layer, as shown in FIG. 21. The second insulator layer may be produced by anodizing a portion of the seed layer. The semiconductor material to undergo SPC can then be positioned onto this second insulator using techniques such as hot wire deposition, PECVD, chemical deposition such as liquid deposition or LPCVD, or PVD. FIG. 21 shows this processing when it has progressed to the point where a typical trench is shown having been created down through this semiconductor to the seed layer. The pattern transfer to establish the trench positions is attained using a resist on the material to undergo SPC. The trench position patterning may include involvement of conventional optical lithography, holography, stamping, or imprinting, including a role-to-role format for the latter two, and etching of the material to undergo SPC. After the positioning of trenches for the first set of electrode elements and the disposition of the first electrode element set, the processing may proceed similar to that shown in FIGS. 19D-19G (the seed layer and over-coating second insulator layer present in this version are not shown in FIGS. 19D-19G) with SPC carried out. The trenches for the second set of electrode elements are not created deep enough to penetrate the second insulator layer in this approach. Further, it is to be noted that in this approach a metal foil substrate can function as the seed layer and, in that situation, a first insulator layer covering the substrate is not used. The actual SPC step may be done before or after the creation of the trenches for the second set of electrode elements. The actual SPC step may be done before or after the filling of the trenches used for the fabrication of the counter-electrode elements.

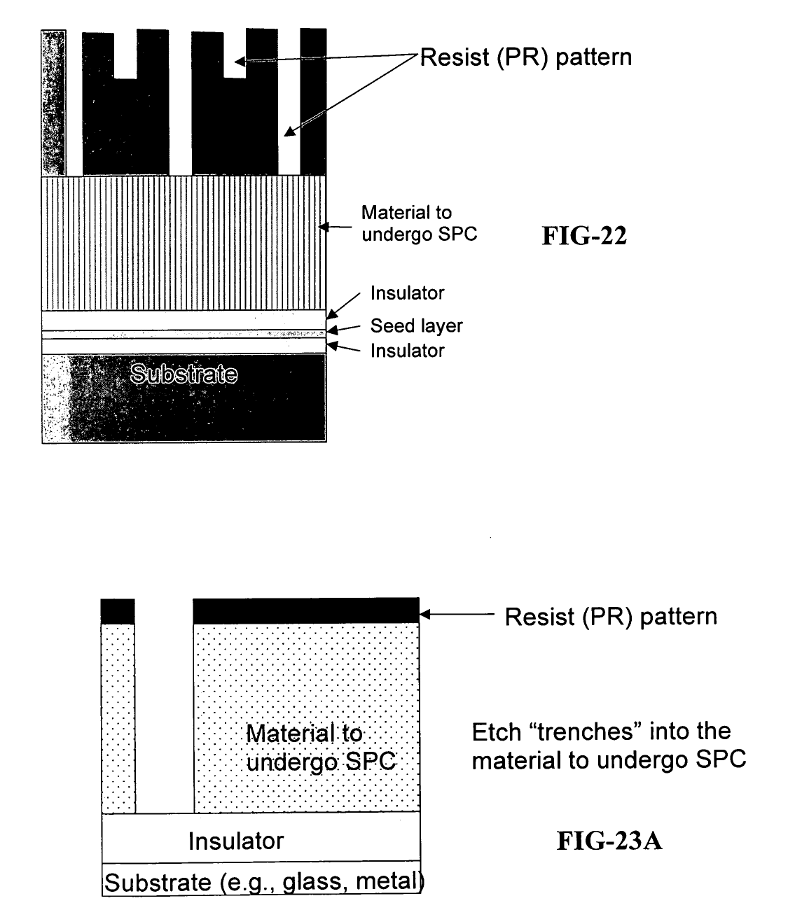

In another embodiment, the pattern that establishes the positions of the trenches for the first set of electrode elements may also be used to establish the positions of the set of counter-electrode elements. For example, imprinting pattern transfer may be used to create the pattern seen in cross-section of FIG. 22. Such imprinting can be done by roll-to-roll techniques. By imprinting into a resist starting trenches of two different depths, as seen, different depth trenches can be etched into the material which is to undergo SPC. In this approach, etching of the trenches for the one electrode element set and for the other occurs simultaneously. Adjustment of the trench depth pattern in the resist can allow simultaneous trench etching, for example, to reach the seed layer for all the first electrode elements but not to reach or just reach the insulator layer for the set of counter-electrode elements. Once this has been achieved, processing may proceed as shown in FIGS. 19D-19G (with the second set of trenches, the seed layer and the over-coating second insulator layer not shown). It is to be noted that in this approach also, a metal foil substrate can function as the seed layer and, in that situation, a first insulator layer covering the substrate is not used. In addition, the actual SPC step may be done before or after the filling of the trenches used for the fabrication of the counter-electrode elements or it may be done and then a second completing etching of the second set of trenches is undertaken.

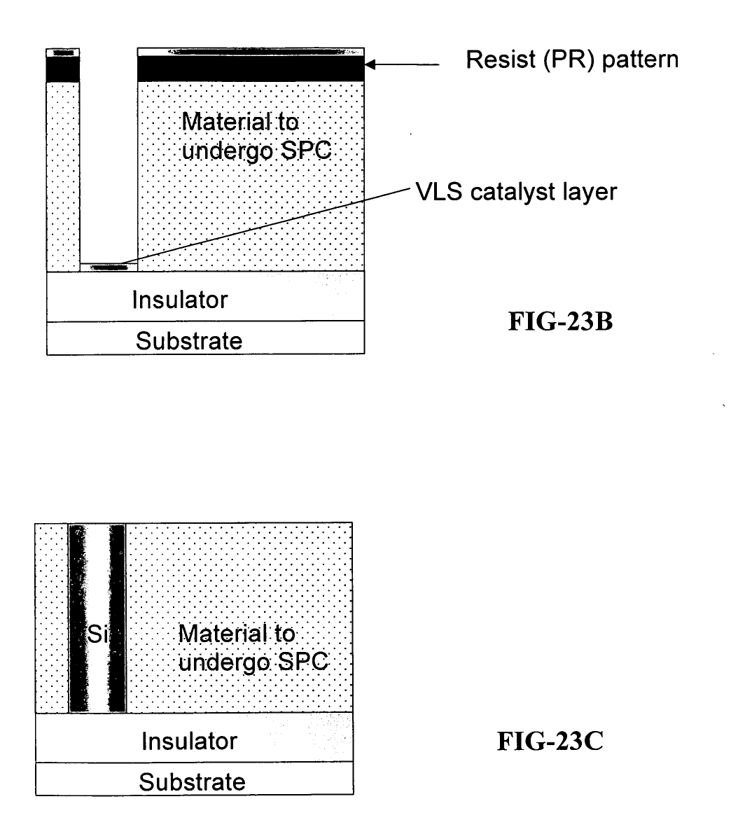

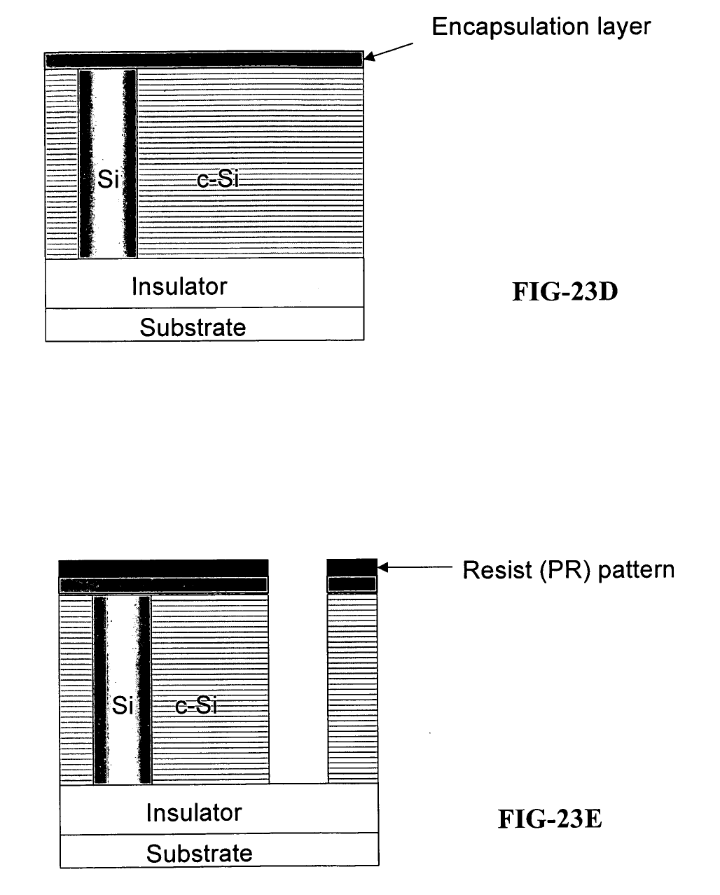

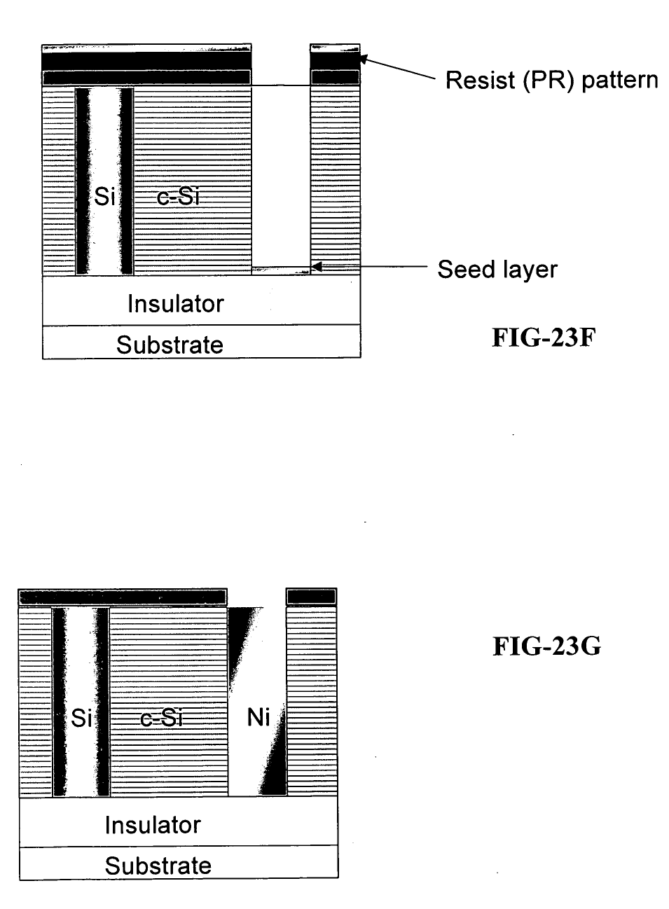

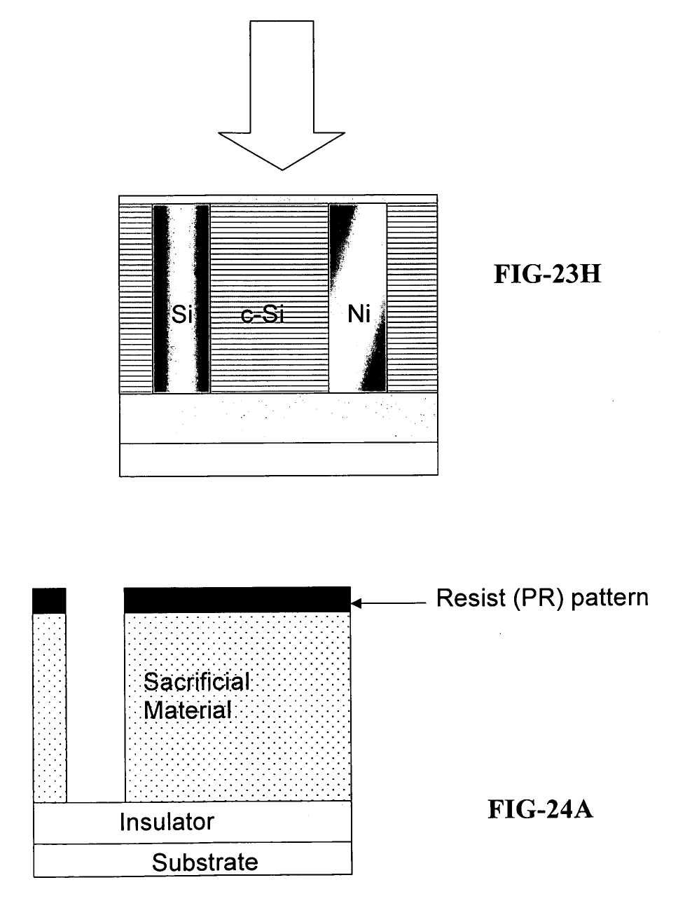

Semiconductor induced solid phase crystallization may be used in place of metal induced solid phase crystallization. We now discuss this in depth in terms of silicon induced solid phase crystallization. Silicon induced solid phase crystallization (SISPC) may be used in place of metal induced solid phase crystallization. SISPC uses silicon grown by low temperature VLS (e.g., silicon nanowires) to act as a catalyst for SPC rather than a using an SPC catalyst metal. SISPC thereby avoids any contamination possibilities in the active layer from an SPC metal catalyst. This same Si may then play the role of the first electrode elements also. An example embodiment is seen in FIGS. 23A-23H. FIGS. 23A and 23B show an approach to creating the first set of trenches with the necessary VLS catalyst at their bottom. In FIG. 23C, VLS Si (e.g., in the form of multiple silicon nanowires (SiNWs)) is grown in these trenches of the first set of electrode elements. There are a number of well know VLS catalysts for VLS Si growth including Ti and Au. Using Au as the VLS catalyst, for example, VLS Si growth may be done using a temperature range of about 450 to 500° C. In this embodiment, the set of electrode elements/SPC catalyst is taken as the cathode; therefore this Si SPC catalyst is doped n-type during growth. After positioning of the Si SPC catalyst, the material may be crystallized using SPC. As shown in FIG. 23D, an optional encapsulation layer, such as silicon nitride, may be placed on the structure. The counter-electrode elements are created as shown FIGS. 23E-23H. Specifically, the c-Si can be etched for the counter-electrode elements as shown in FIG. 23E, a seed layer can be applied having a thickness of about 100 nm as shown in FIG. 23F and the counter-electrode element is deposited, for example, by electrodeposition. The actual SPC step may be done before or after the creation of the trenches used for the fabrication of the counter-electrode elements. This figure shows high work function Ni counter-electrode elements, as an example. Since the first electrode was taken to be the cathode in FIG. 23E, the counter-electrode can be composed of a high work function material, such as Ni or p-Si. The latter may be created by another application of a VLS catalyst layer at the bottom of the trenches which will house the anode and subsequent VLS deposition.

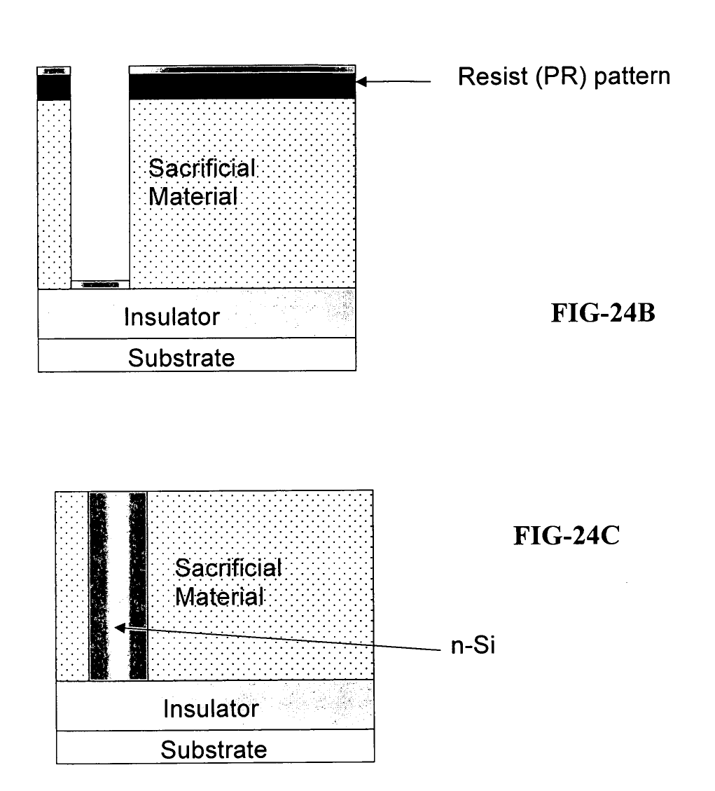

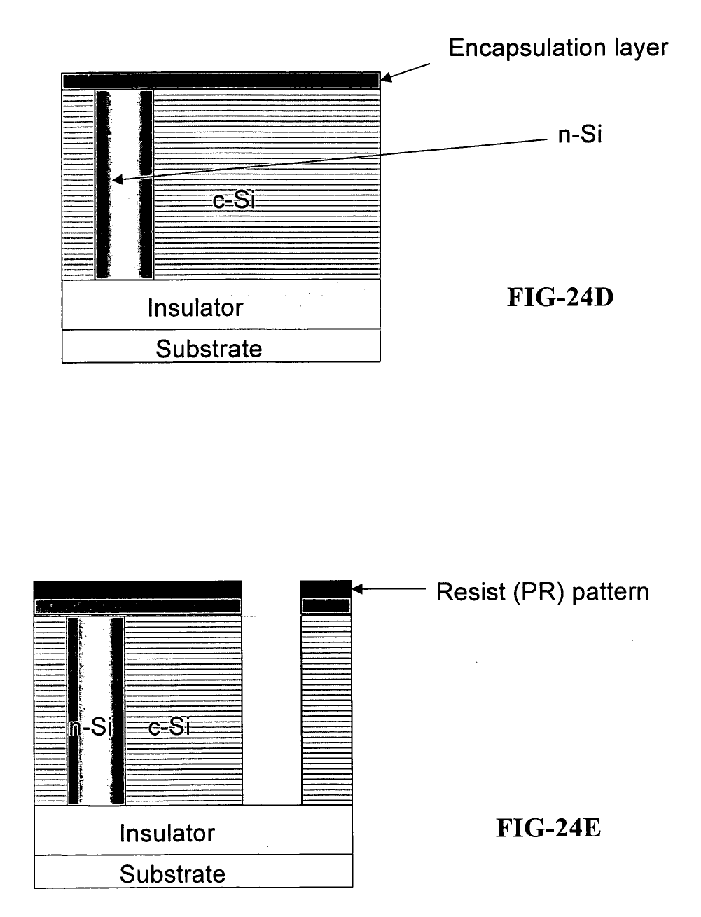

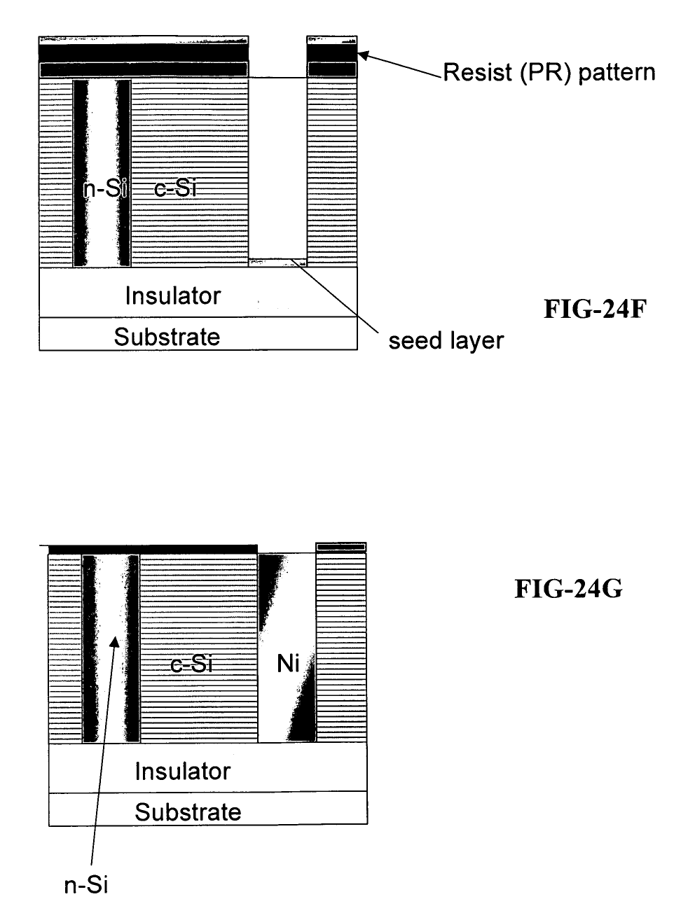

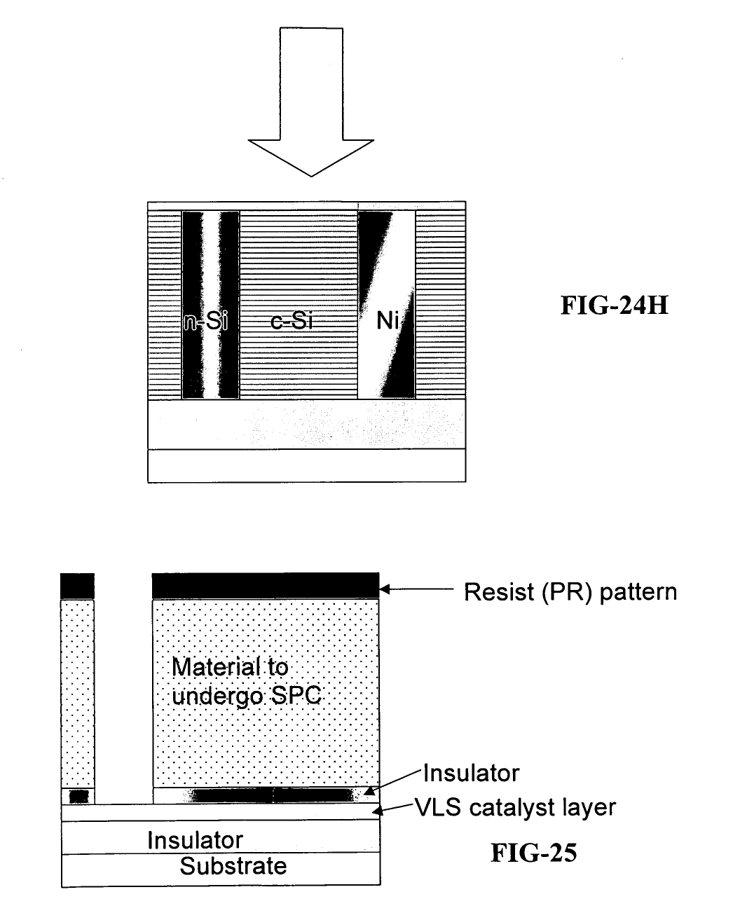

There is an alternative version of the process shown in FIGS. 23A-23H in which a sacrificial layer is first used. This alternative embodiment is seen in FIGS. 24A-24H. After growing the Si by VLS (in this embodiment, the first set of electrode elements is taken to be cathode elements) in the first set of trenches as shown in FIG. 24C, the sacrificial layer used to define this first set of trenches is removed (not shown). This allows etching removal of VLS catalyst present before depositing the a-Si to undergo SISPC thereby removing impurities that may affect photo-carrier collection. SISPC is then done and the result is shown FIG. 24D. The remainder of the processing proceeds as discussed above. After the material to undergo SISPC (a-Si in this example) is deposited, the etching of the second set of trenches may be accomplished before or after SISPC.

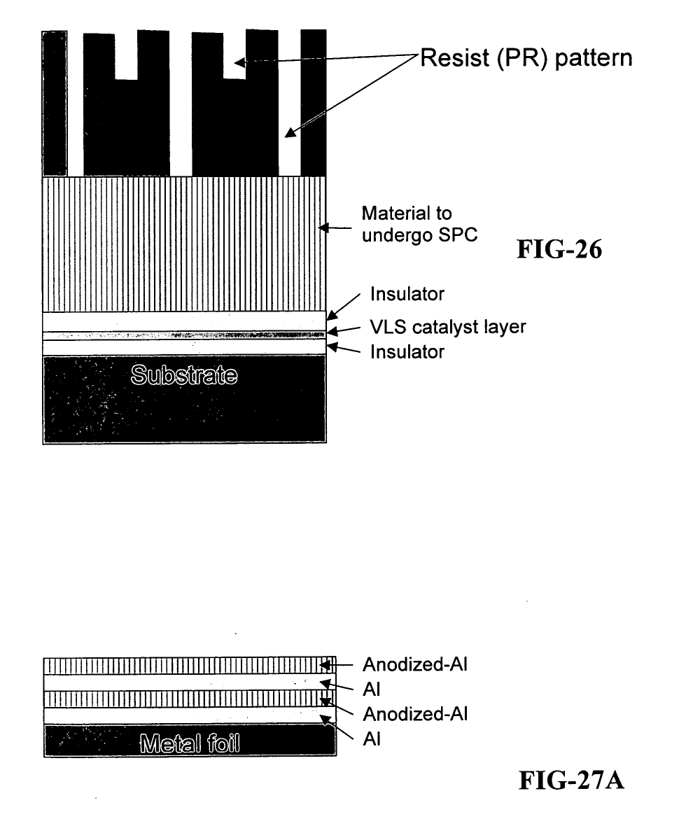

SISPC may also be used with the structures shown in FIGS. 25 and 26. In these embodiments, the VLS catalyst is present across the substrate, and can function in the interconnecting, as is always the situation. Using the resist pattern shown in FIGS. 25 and 26, trenches are etched into the material to undergo SISPC. In one embodiment, a trench positioning scheme as shown in FIG. 25 can be obtained where the first set of trenches is etched down to a VLS catalyst layer. The low temperature silicon SPC catalyst is then grown in the set of trenches of the embodiment of FIG. 25 using the VLS catalyst layer or grown in the deeper set of trenches created in the material to undergo SISPC going down to the VLS catalyst as shown in FIG. 26. This SISPC catalyst Si is doped n type (cathode) or p-type (anode) depending on the role selected for this set of electrode elements. The processing then proceeds in FIGS. 25 and 26 as discussed above (without the second insulator nor VLS catalyst layer being shown). The tailoring of the material to be used for the second set of electrode elements is dictated by their anode or cathode role.

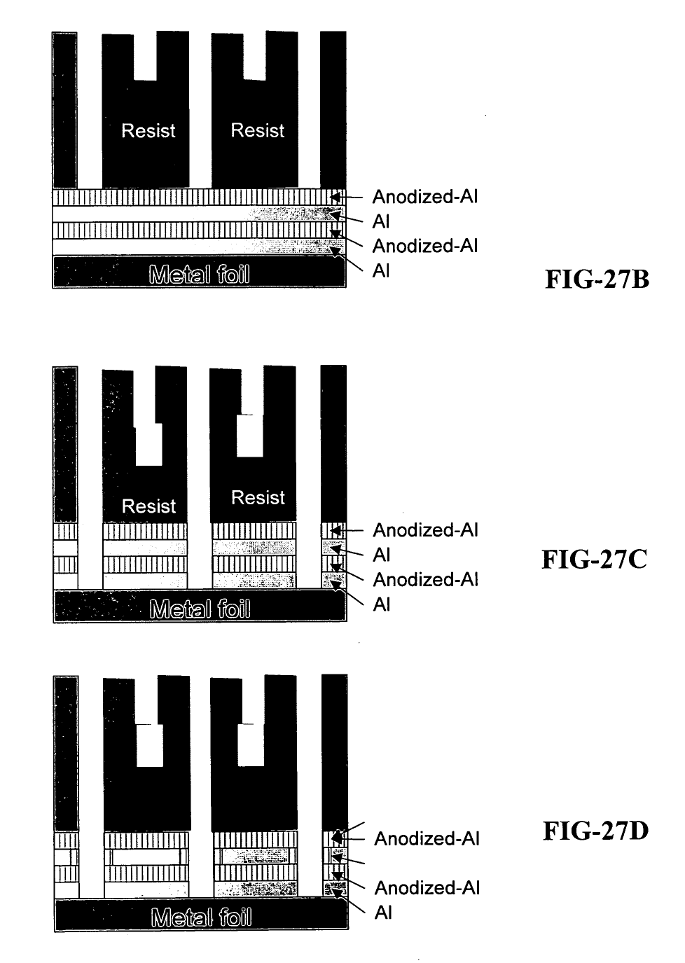

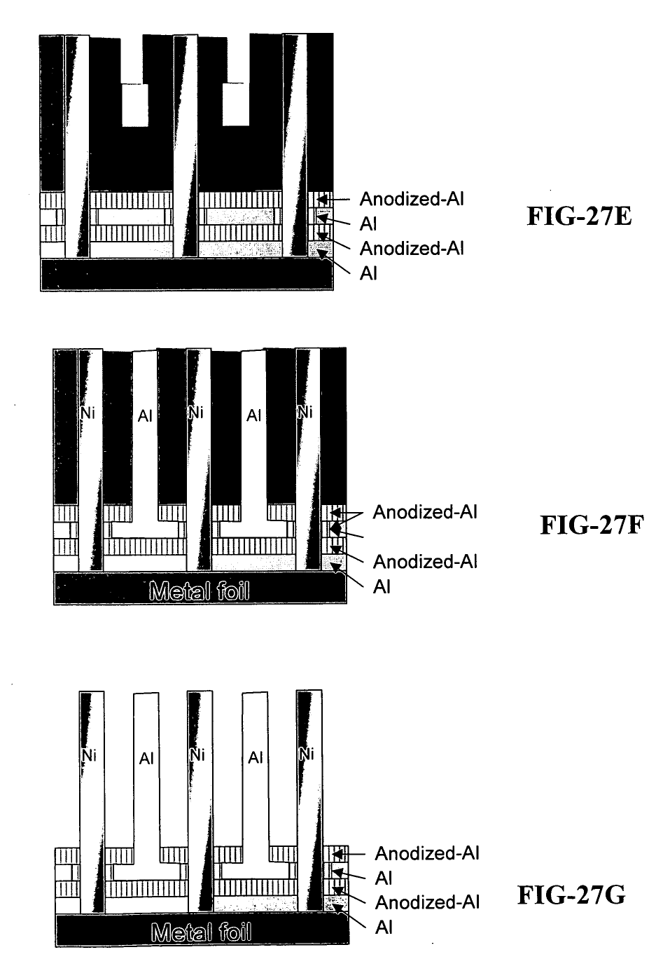

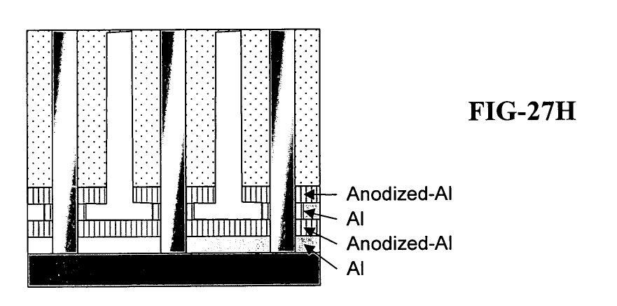

In another exemplary embodiment, imprinting done, for example, by roll-to-roll technology previously cited, is used to create a set of deep and shallow trenches in a resist as shown FIG. 27B. In this example the substrate is taken to be a metal foil covered with two alternating metal and insulator layer pairs. Of course, a glass foil or plastic may be used as the substrate. When the substrate is a metal, it may serve as the first metal layer, if consistent with the cell “wiring” desired. For definitiveness, FIGS. 27A-27H depicts the metal layers as Al and the insulator layers as anodized Al. As seen in FIG. 27C, the differences in the original trench depths in the resist combined with etch selectivity differences once the resist is cleared in the deeper set of trenches allows dry etching of the deeper set of trenches. FIG. 27D shows anodization being used to turn the second metal layer areas adjacent to the completed set of trenches into an insulating region. FIG. 27E shows Ni, as an example, being electro-deposited thereby forming the first set of electrode elements. Since Ni was chosen in this example, these elements constitute the anode. Finally, FIG. 27F shows the trenches being completed for the counter-electrode elements and being filled. Here Al is shown as an exemplary low work function material. FIGS. 27G and 27H depict the resist removal and the active layer positioning. Here the deposition of Si, which may be a-Si or polycrystalline, is shown, as an example. If the former is used, then Ni may be used for SPC. In that alternative, Al would be filled into the second set of trenches after SPC or would not be used for the low work function cathode material. The completed structure is shown in FIG. 27H.

It is to be noted that all the lateral collection structures seen in FIGS. 19-27 may be used without SPC. The fabrication proceeds as discussed in all these examples with the omission of the SPC step. Ni and other metal induced SPC metals as well as SISPC Si produced by VLS may continue to be used as electrode elements in such structures but their SPC inducing properties are not used; i.e., the processing temperatures are below those needed for SPC. In addition, since SPC is not done in this situation, other materials such as Ag, etc., become candidates for the electrode elements. It is to be noted, also, that surface treatments for the electrode elements such as converting Ni into NiO by UV ozone exposure or the use of SAMs on elements may be used in all these structures. This may be done to exploit the voltage contributed by band edge steps, to attain hole transport/electron blocking or electron transport/ hole blocking layer features as desired at electrode-elements, or both. The spacing of the lateral collection elements in the structures of FIGS. 19-27 may be at the nano-scale or micro-scale as dictated by the collection length property of the active layer. In these structures, the width of the electrode elements should be minimized, as much as is technologically possible, unless they are semiconductor (absorber) materials. It should also be noted that, while explicit reference is given to metal or glass substrates, including metal and glass foil substrates, is made in these embodiments, plastic and composite substrates may be employed.

It should be understood that the application of the various lateral collection structures is not limited to the details or methodology set forth in the description or illustrated in the figures. It should also be understood that the phraseology and terminology employed herein is for the purpose of description only and should not be regarded as limiting. While the exemplary embodiments illustrated in the figures and described are presently preferred, it should be understood that these embodiments are offered by way of example only. Accordingly, the present application is not limited to a particular embodiment, but extends to various modifications that nevertheless fall within the scope of the appended claims. The order or sequence of any processes or method steps may be varied or re-sequenced according to alternative embodiments.

It is important to note that the construction and arrangement of the structures as shown in the various exemplary embodiments is illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited in the claims. For example, elements shown as integrally formed may be constructed of multiple parts or elements, the position of elements may be reversed or otherwise varied, and the nature or number of discrete elements or positions may be altered or varied. Accordingly, all such modifications are intended to be included within the scope of the present application. The order or sequence of any process or method steps may be varied or re-sequenced according to alternative embodiments. In the claims, any means-plus-function clause is intended to cover the structures described herein as performing the recited function and not only structural equivalents but also equivalent structures. Other substitutions, modifications, changes and omissions may be made in the design, operating conditions and arrangement of the exemplary embodiments without departing from the scope of the present application.

What is claimed is:

1. A lateral collecting photovoltaic structure comprising:
a plurality of alternating anode and cathode collecting elements disposed in an active layer, wherein in positions of the collecting elements being determined by pattern transfer of an alternating depth trench pattern into a material to undergo solid phase crystalization such that one depth corresponds to the elements of an electrode and the other depth corresponds to the elements of the counter-electrode;
a deeper set of trenches being enhanced in depth to reach through an insulator to an electrically conducting layer disposed across a substrate and a second shallower set of trenches terminates in the material to undergo solid phase crystallization;
the shallower set of trenches having an electrically conducting material at a trench bottom;
the metal electrode collecting elements disposed on said conducting layer and said material; and
at least one of which set of elements also serving to enhance solid phase crystallization thereby resulting a crystalline phase active layer from the material undergoing solid phase crystallization.

2. A lateral collecting photovoltaic structure comprising:
alternating anode and cathode collecting elements in an active layer;
said element positions determined by pattern transfer of an alternating depth trench pattern into the active layer material such that one depth corresponds to the elements of an electrode and the other depth corresponds to the elements of the counter-electrode;
where the deeper set of trenches is enhanced in depth to reach through an insulator to an electrically conducting layer disposed across the substrate;
and where the second shallower set of trenches terminates in the active layer;
where the shallower set of trenches has an electrically conducting material at the trench bottom; and
with metal electrode elements disposed on the said layer and said material and serving as electrode and counter-electrode.

3. A lateral collecting photovoltaic structure comprising:
alternating anode and cathode collecting elements in an active layer;
said element positions determined by pattern transfer of an alternating depth trench pattern into amorphous silicon to undergo solid phase crystallization such that one depth corresponds to the elements of an electrode and the other depth corresponds to the elements of the counter-electrode;
where the deeper set of trenches is enhanced in depth to reach through an insulator to an electrically conducting layer disposed across the substrate;
and where the second shallower set of trenches terminates in the material to undergo solid phase crystallization;
where the shallower set of trenches has an electrically conducting material at the trench bottom;
where at least one of said conducting layer or conducting material is a catalyst for vapor-liquid-solid silicon growth;
thereby giving in at least one set of trenches doped semiconductor growth of a material to serve as the catalyst for silicon induced solid phase crystallization; and
with at least said one of which set of elements resulting in the active layer amorphous silicon undergoing solid phase crystallization.

4. The structure of claim 3 in which all silicon materials are replaced with another semiconductor.
